(19) United States
(12) Patent Application Publication
(10) Pub. No.: US 2025/0081338 A1
(43) Pub. Date: Mar. 6, 2025

(54) PRINTED CIRCUIT BOARD AND METHOD OF MANUFACTURING THE SAME

(71) Applicant: SAMSUNG ELECTRO-MECHANICS CO., LTD., Suwon-si (KR)

(72) Inventors: Sang Ho JEONG, Suwon-si (KR); Jong Eun PARK, Suwon-si (KR); Chang Hwa PARK, Suwon-si (KR); Hyun Hu LEE, Suwon-si (KR)

(73) Assignee: SAMSUNG ELECTRO-MECHANICS CO., LTD., Suwon-si (KR)

(21) Appl. No.: 18/769,762

(22) Filed: Jul. 11, 2024

(30) Foreign Application Priority Data
Sep. 6, 2023 (KR) 10-2023-0118607
Dec. 27, 2023 (KR) 10-2023-0192933

(51) Int. Cl. H05K 1/02; H05K 1/11; H05K 3/40; H05K 3/46

(52) U.S. Cl. CPC H05K 1/0298; H05K 1/115; H05K 3/4038; H05K 3/4644; H05K 2201/096; H05K 2201/09827; H05K 2201/2081

(57) ABSTRACT

A printed circuit board includes: a first insulating layer; a first wiring layer embedded in the first insulating layer on one side thereof; a glass layer disposed on the other side, opposite to the one side of the first insulating layer; a second wiring layer disposed on the glass layer; and a first via layer connecting the first wiring layer and the second wiring layer to each other, and including a first via portion penetrating the glass layer and a second via portion penetrating the first insulating layer. In a cross-sectional view of the printed circuit board, at least one of the first via portion and the second via portion has a width becoming substantially narrower toward the first wiring layer.

### CROSS-REFERENCE TO RELATED APPLICATION(S)

This application claims benefit of priority to Korean Patent Applications Nos. 10-2023-0118607 filed on Sep. 6, 2023 and 10-2023-0192933 filed on Dec. 27, 2023 in the Korean Intellectual Property Office, the disclosures of which are incorporated herein by reference in its entirety.

### TECHNICAL FIELD

The present disclosure relates to a printed circuit board and a method of manufacturing the same.

### BACKGROUND

In order to process data that has increased exponentially due to recent developments in artificial intelligence (AI) technology and the like, multi-chip packages including memory chips, such as a high bandwidth memory (HBM), and processor chips, such as a central processing unit (CPU), a graphics processing unit (GPU), an application specific integrated circuit (ASIC), and a field programmable gate array (FPGA), are being used. Accordingly, there is a demand for substrates with large-area structures, and efforts are continuing to overcome problems involving flatness and warpage control.

### SUMMARY

An aspect of the present disclosure may provide a printed circuit board including a glass layer and a method of manufacturing the same.

Another aspect of the present disclosure may provide a printed circuit board capable of preventing warpage with improved flatness and a method of manufacturing the same.

Another aspect of the present disclosure may provide a printed circuit board capable of improving reliability and a method of manufacturing the same.

According to an aspect of the present disclosure, a printed circuit board may include: a first insulating layer; a first wiring layer embedded in the first insulating layer on one side thereof; a glass layer disposed on the other side, opposite to the one side of the first insulating layer; a second wiring layer disposed on the glass layer; and a first via layer connecting the first wiring layer and the second wiring layer to each other, and including a first via portion penetrating the glass layer and a second via portion penetrating the first insulating layer. In a cross-sectional view of the printed circuit board, at least one of the first via portion and the second via portion may have a width becoming substantially narrower toward the first wiring layer.

According to another aspect of the present disclosure, a printed circuit board may include: an insulating layer; a first wiring layer disposed on one side of the insulating layer; a glass layer disposed on the other side, opposite to the one side of the insulating layer; a via layer including a first through-hole penetrating the insulating layer and exposing at least a portion of the first wiring layer, a second through-hole penetrating the glass layer and connected to the first through-hole, a portion of a first metal layer disposed on at least the partially exposed portion of the first wiring layer and a wall of each of the first and second through-holes, and a portion of a second metal layer disposed on the first metal layer and filling at least a portion of each of the first and second through-holes; and a second wiring layer disposed on the glass layer and connected to the via layer.

According to another aspect of the present disclosure, a method of manufacturing a printed circuit board may include: forming a first insulating layer embedding a first wiring layer; forming a glass layer on the first insulating layer; forming a first through-hole penetrating the glass layer; forming a second through-hole penetrating the first insulating layer and exposing at least a portion of the first wiring layer; forming a first via layer in the first through-hole and the second through-hole; and forming a second wiring layer connected to the first via layer on the first insulating layer.

According to another aspect of the present disclosure, a printed circuit board may include: a first insulating layer; a glass layer disposed on the first insulating layer; a plurality of wiring layers including first and second wring layers respectively attached to the first insulating layer and the glass layer; and a via layer connecting the first wiring layer and the second wiring layer to each other, and including a first via portion disposed in the glass layer and a second via portion extending from the first via portion and disposed in the first insulating layer. A surface roughness of one surface of the glass layer facing the first insulating layer may be smaller than a surface roughness of another surface of the glass layer opposing the one surface of the glass layer.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIG. 3 is a schematic cross-sectional view of a portion of a printed circuit board according to a first exemplary embodiment;

FIGS. 4A to 4C are schematic cross-sectional views illustrating a portion of a method of manufacturing a printed circuit board according to the first exemplary embodiment;

FIGS. 5A to 5J are schematic cross-sectional views illustrating printed circuit boards and parts of methods of manufacturing the same according to first to tenth modifications of the first exemplary embodiment;

FIG. 5K is plan views illustrating a portion of the method of manufacturing a printed circuit board according to the ninth or tenth modification of the first exemplary embodiment illustrated in FIG. 5I or 5J;

FIG. 6 is a schematic cross-sectional view of a portion of a printed circuit board according to a second exemplary embodiment;

FIGS. 7A to 7C are schematic cross-sectional views illustrating a portion of a method of manufacturing a printed circuit board according to the second exemplary embodiment;

FIG. 8 illustrates schematic cross-sectional views for explaining a printed circuit board and a portion of a method of manufacturing the same according to a first modification of the second exemplary embodiment;

FIG. 9 is a schematic cross-sectional view of a portion of a printed circuit board according to a third exemplary embodiment;

FIGS. 10A to 10C are schematic cross-sectional views illustrating a portion of a method of manufacturing a printed circuit board according to the third exemplary embodiment;

FIGS. 11A and 11B are schematic cross-sectional views illustrating printed circuit boards and parts of methods of manufacturing the same according to first and second modifications of the third exemplary embodiment;

FIGS. 12A to 12E illustrate schematic cross-sectional views of printed circuit boards according to first to fifth application examples of the first exemplary embodiment;

FIGS. 13A to 13D are schematic cross-sectional views illustrating a method of manufacturing the printed circuit board according to the first application example of the first exemplary embodiment illustrated in FIG. 12A;

FIGS. 14A to 14D are schematic cross-sectional views illustrating a method of manufacturing the printed circuit board according to the second application example of the first exemplary embodiment illustrated in FIG. 12B;

FIGS. 15A and 15B illustrate schematic cross-sectional views of printed circuit boards according to sixth and seventh application examples of the first exemplary embodiment; and

FIGS. 16A to 16D are schematic cross-sectional views illustrating a method of manufacturing the printed circuit board according to the sixth application example of the first exemplary embodiment illustrated in FIG. 15A.

### DETAILED DESCRIPTION

Hereinafter, exemplary embodiments of the present disclosure will now be described in detail with reference to the accompanying drawings.

### Electronic Device

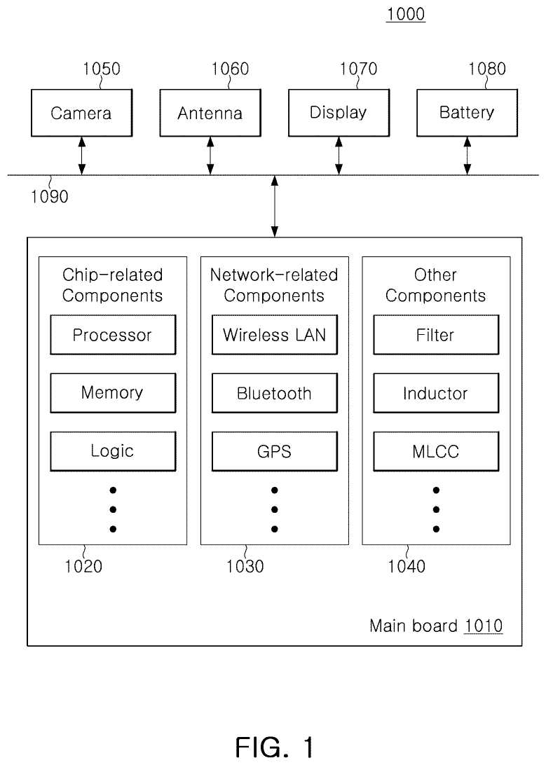

FIG. 1 is a schematic block diagram illustrating an example of an electronic device system.

Referring to FIG. 1, an electronic device 1000 may accommodate a mainboard 1010 therein. The mainboard 1010 may include chip-related components 1020, network-related components 1030, and other components 1040, which are physically and/or electrically connected thereto. These components may be connected to other electronic components to be described below to form various signal lines 1090.

The chip-related components 1020 may include a memory chip such as a volatile memory (e.g., a dynamic random access memory (DRAM)), a non-volatile memory (e.g., a read only memory (ROM)), or a flash memory; an application processor chip such as a central processor (e.g., a central processing unit (CPU)), a graphics processor (e.g., a graphics processing unit (GPU)), a digital signal processor, a cryptographic processor, a microprocessor, or a microcontroller; and a logic chip such as an analog-digital converter or an application-specific integrated circuit (ASIC). The chip-related components 1020 are not limited thereto, but may also include other types of chip-related electronic components. In addition, these chip-related components 1020 may be combined with each other. The chip-related components 1020 may be in the form of a package including the chips or electronic components described above.

The network-related components 1030 may include protocols such as wireless fidelity (Wi-Fi) (Institute of Electrical and Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+(HSPA+), high speed downlink packet access+(HSDPA+), high speed uplink packet access+(HSUPA+), global system for mobile communications (GSM), enhanced data GSM environment (EDGE), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols designated after the abovementioned protocols. However, the network-related components 1030 are not limited thereto, but may also include a variety of other wireless or wired standards or protocols. In addition, the network-related components 1030 may be combined with each other, together with the chip-related components 1020.

The other components 1040 may include a high frequency inductor, a ferrite inductor, a power inductor, ferrite beads, a low temperature co-fired ceramic (LTCC), an electromagnetic interference (EMI) filter, a multi-layer ceramic capacitor (MLCC), and the like. However, the other components 1040 are not limited thereto, but may also include passive elements in chip component type used for various other purposes, and the like. In addition, the other components 1040 may be combined with each other, together with the chip-related components 1020 and/or the network-related components 1030.

Depending on the type of electronic device 1000, the electronic device 1000 may include other electronic components that may or may not be physically and/or electrically connected to the mainboard 1010. Examples of the other electronic components may include a camera 1050, an antenna 1060, a display 1070, a battery 1080, and the like. The other electronic components are not limited thereto, but may be an audio codec, a video codec, a power amplifier, a compass, an accelerometer, a gyroscope, a speaker, a mass storage unit (e.g., a hard disk drive), a compact disk (CD), a digital versatile disk (DVD), and the like. The other electronic components may also include other electronic components and the like used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

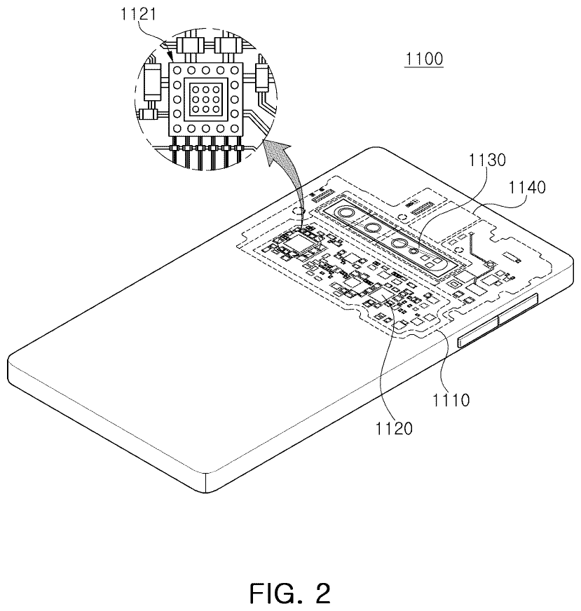

FIG. 2 is a schematic perspective view illustrating an example of an electronic device.

Referring to FIG. 2, the electronic device may be, for example, a smartphone 1100. A motherboard 1110 may be accommodated in the smartphone 1100, and various components 1120 may be physically and/or electrically connected to the motherboard 1110. Also, other components that may or may not be physically and/or electrically connected to the motherboard 1110, such as a camera module 1130 and/or a speaker 1140, may be accommodated in the smartphone 1100. Some of the components 1120 may be the above-described chip-related components, e.g., a component package 1121, but are not limited thereto. The component package 1121 may be in the form of a printed circuit board on which electronic components including active components and/or passive components are surface-mounted. Alternatively, the component package 1121 may be in the form of a printed circuit board in which active components and/or passive components are embedded. Meanwhile, the electronic device is not necessarily limited to the smartphone 1100, and may be any other electronic device as described above.

### Printed Circuit Board and Method of Manufacturing Printed Circuit Board

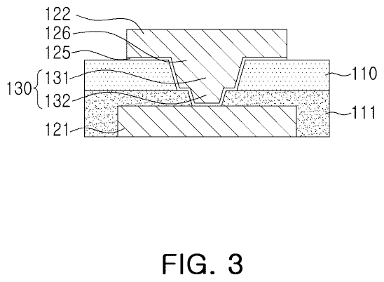

FIG. 3 is a schematic cross-sectional view of a portion of a printed circuit board according to a first exemplary embodiment. Specifically, FIG. 3 is a cross-sectional view illustrating an insulating structure between a first wiring layer 121 and a second wiring layer 122 of the portion of the printed circuit board according to the first exemplary embodiment.

Referring to FIG. 3, the printed circuit board according to the first exemplary embodiment may include a first insulating layer 111, a first wiring layer 121 embedded in one side of the first insulating layer 111, a glass layer 110 disposed on the other side, opposite to the one side of the first insulating layer 111, a second wiring layer 122 disposed on the glass layer 110, and a first via layer 130 connecting the first wiring layer 121 and the second wiring layer 122 to each other, and including a first via portion 131 penetrating the glass layer 110 and a second via portion 132 penetrating the first insulating layer 111. The first via layer 130 may include a seed layer 125 and a plating layer 126.

In the printed circuit board according to the first exemplary embodiment, the first insulating layer 111 and the glass layer 110 may be included between the first wiring layer 121 and the second wiring layer 122. That is, the insulating structure between the first wiring layer 121 and the second wiring layer 122 in the printed circuit board according to the first exemplary embodiment is not constituted by a single layer or an organic insulating layer alone, and the glass layer 110 may be included therein. As the glass layer 110 is included in the insulating structure between the first wiring layer 121 and the second wiring layer 122, the printed circuit board can be excellent in flatness, and can be resistant to warpage during the manufacturing stage.

The printed circuit board according to the first exemplary embodiment may not use the glass layer 110 as a core, but may include the glass layer 110 and the first insulating layer 111 as build-up layers. Therefore, based on FIG. 3, which illustrates only the portion of the printed circuit board according to the first exemplary embodiment, other build-up insulating layers may be additionally disposed on the upper and lower sides, a core layer may be additionally disposed on the lower side, or a solder resist layer may be disposed on the lower side such that the first wiring layer 121 is disposed on the outermost side of the printed circuit board with an embedded pattern to form a so-called coreless type printed circuit board. Only the insulating structure between the first wiring layer 121 and the second wiring layer 122 and the interlayer connection using the first via layer 130 are illustrated in FIG. 3, and modifications thereof, other exemplary embodiments, and various examples where the printed circuit board is applied will be described later with reference to other drawings.

The first insulating layer 111 may include an organic insulating material. The organic insulating material may include a thermosetting resin such as an epoxy resin, a thermoplastic resin such as a polyimide, or a material containing an inorganic filler, an organic filler, and/or a glass fiber, a glass cloth or a glass fabric together with the resin. For example, the insulating material may be a non-photosensitive insulating material such as Ajinomoto build-up film (ABF) or prepreg (PPG), but is not limited thereto, and another type of polymer material may be used as an insulating material. Alternatively, the insulating material may be a photosensitive insulating material such as photoimageable dielectric (PID). In addition, the insulating material may include an adhesive sheet such as a bonding sheet (BS). Specifically, the first insulating layer 111 may preferably include an Ajinomoto build-up film (ABF), but is not limited thereto, and may include another organic insulating material. Meanwhile, the first insulating layer 111 is illustrated as one insulating layer in FIG. 3, but is not necessarily limited thereto. If necessary, the first insulating layer 111 may be constituted by a plurality of insulating layers, and may further include a configuration that can be used by those skilled in the art.

The first wiring layer 121 may be embedded on one side of the first insulating layer 111. That is, the first wiring layer 121 may be disposed on one side of the first insulating layer 111, so that one surface of the first wiring layer 121 is exposed from one surface of the first insulating layer 111. At this point, the exposure of one surface of the first wiring layer 121 from one surface of the first insulating layer 111 means that one surface of the first wiring layer 121 is not covered by the first insulating layer 111. Even if one surface of the first wiring layer 121 is covered by another component further included under the first insulating layer 111, this may be understood to have the same meaning as described above. That is, this may be meant that one surface of the first wiring layer 121 is not covered by the first insulating layer 111, and the other surface opposite to one surface of the first wiring layer 121 and the side surface of the first wiring layer 121 are covered by the first insulating layer 111. At this time, unless another adhesive means is additionally included between the first wiring layer 121 and the first insulating layer 111, the other surface and the side surface of the first wiring layer 121 may be in contact with the first insulating layer 111.

The first wiring layer 121 may include metal. The metal may include copper (Cu), aluminum (Al), silver (Ag), tin (Sn), gold (Au), nickel (Ni), lead (Pb), titanium (Ti), and/or alloys thereof. The first wiring layer 121 may preferably include copper (Cu), but is not limited thereto.

The first wiring layer 121 may perform various functions each depending on design. For example, the first wiring layer 121 may include a signal pattern, a power pattern, a ground pattern, or the like. Each of these patterns may have various forms such as lines, planes, and pads. The first wiring layer 121 may include an electroless plating layer (or chemical copper) and an electrolytic plating layer (or electric copper). Alternatively, the first wiring layer 121 may include a metal foil (or a copper foil) and an electrolytic plating layer (or electric copper). Alternatively, the first wiring layer 121 may include a metal foil (or a copper foil), an electroless plating layer (or chemical copper), and an electrolytic plating layer (or electric copper). The first wiring layer 121 may include a sputtering layer instead of the electroless plating layer (or chemical copper), or the first wiring layer 121 may include both a sputtering layer and an electroless plating layer (or chemical copper) if necessary.

The first wiring layer 121 may be formed using any one technique among a semiadditive process (SAP), a modified semiadditive process (MSAP), a tenting (TT) process, and a subtractive process, but is not limited thereto. Any technique may be used without limitation if the technique is capable of configuring a circuit on a printed circuit board. In addition, the first wiring layer 121 may be formed using a different technique depending on the purpose of use and the design.

The glass layer 110 may include glass, which is an amorphous solid. For example, the glass may include pure silicon dioxide (about 100% SiO2), soda lime glass, borosilicate glass, alumino-silicate glass, or the like. However, the glass layer 110 is not limited thereto, and an alternative glass material such as fluorine glass, phosphate glass, or chalcogen glass may also be used as a material for the glass layer 110. In addition, the glass layer 110 may further include other additives to form glass with particular physical properties. These additives may include not only calcium carbonate (e.g., lime) and sodium carbonate (e.g., soda), but also magnesium, calcium, manganese, aluminum, lead, boron, iron, chromium, potassium, sulfur, antimony, and carbonates and/or oxides of these elements and other elements. The glass layer 110 is a layer that is distinguished from the material containing a glass fiber, a glass cloth, a glass fabric, or the like, such as copper clad laminate (CCL) or prepreg (PPG), and may be understood as, for example, a plate glass or a glass sheet.

The printed circuit board according to the first exemplary embodiment, which includes the glass layer 110, can be basically excellent in flatness, and can also be advantageous in controlling warpage through a low coefficient of thermal expansion (CTE) or the like. In particular, since the printed circuit board according to the first exemplary embodiment may have the glass layer 110 as a part of a build-up layer, this may be more advantageous in controlling warpage even in a subsequent step of stacking another insulating layer. That is, even if other insulating layers are sequentially stacked on the glass layer 110, the flatness can be further increased, which is more advantageous in forming a high-density fine circuit with a fine pitch. In particular, unlike a case in which the glass layer 110 is used as a core layer, the glass layer 110 may be included in a coreless type substrate, which is advantageous in controlling a warpage characteristic that is a problem of the coreless type substrate. In addition, the glass layer 110 used in the core-type substrate is also capable of controlling a warpage characteristic, thereby increasing reliability, for example, achieving an asymmetric substrate.

In addition, the glass layer 110 can reduce the number of layers in the printed circuit board and further increase the degree of design freedom through the feature of glass having variable dielectric properties, such as Dk of 2.5 to 11.

The second wiring layer 122 may be included on the glass layer 110. The second wiring layer 122 may include metal. The metal may include copper (Cu), aluminum (Al), silver (Ag), tin (Sn), gold (Au), nickel (Ni), lead (Pb), titanium (Ti), and/or alloys thereof. The second wiring layer 122 may preferably include copper (Cu), but is not limited thereto.

The second wiring layer 122 may perform various functions each depending on design. For example, the second wiring layer 122 may include a signal pattern, a power pattern, a ground pattern, or the like. Each of these patterns may have various forms such as lines, planes, and pads. The second wiring layer 122 may include an electroless plating layer (or chemical copper) and an electrolytic plating layer (or electric copper). Alternatively, the second wiring layer 122 may include a metal foil (or a copper foil) and an electrolytic plating layer (or electric copper). Alternatively, the second wiring layer 122 may include a metal foil (or a copper foil), an electroless plating layer (or chemical copper), and an electrolytic plating layer (or electric copper). The second wiring layer 122 may include a sputtering layer instead of the electroless plating layer (or chemical copper), or the second wiring layer 122 may include both a sputtering layer and an electroless plating layer (or chemical copper) if necessary.

The second wiring layer 122 may be formed by any one technique among a semiadditive process (SAP), a modified semiadditive process (MSAP), a tenting (TT) process, and a subtractive process, but is not limited thereto. Any technique may be used without limitation if the technique is capable of configuring a circuit on a printed circuit board. In addition, the second wiring layer 122 may be formed using a different method depending on the purpose of use and the design. Meanwhile, the second wiring layer 122 may be formed at the same time as the first via layer 130, but is not limited thereto.

The first via layer 130 may connect the first wiring layer 121 and the second wiring layer 122 to each other, and penetrate at least a portion of each of the first insulating layer 111 and the glass layer 110. The first via layer 130 may include a first via portion 131 penetrating the first insulating layer 111 and a second via portion 132 penetrating the glass layer 110. That is, the first via layer 130 may be formed to fill a through-hole penetrating the first insulating layer 111 and a through-hole penetrating the glass layer 110, and the first via portion 131 penetrating the first insulating layer 111 and the second via portion 132 penetrating the glass layer 110 may be integrally formed.

The first via layer 130 may include a metal. The metal may include copper (Cu), aluminum (Al), silver (Ag), tin (Sn), gold (Au), nickel (Ni), lead (Pb), titanium (Ti), and/or alloys thereof. The first via layer 130 may preferably include copper (Cu), but is not limited thereto. The first via layer 130 may include a filled via that fills a via hole, but may also include a conformal via disposed along a wall of a via hole. The first via layer 130 may perform various functions each depending on design. For example, the first via layer 130 may include a ground via, a power via, a signal via, or the like.

The first via layer 130 may include an electroless plating layer (or chemical copper) and an electrolytic plating layer (or electric copper). The first via layer 130 may include a sputtering layer instead of the electroless plating layer (or chemical copper), or the first via layer 130 may include both a sputtering layer and an electroless plating layer (or chemical copper) if necessary. More specifically, the first via layer 130 may include a seed layer 125 and a plating layer 126 disposed on the seed layer 125.

The seed layer 125 may include an electroless plating layer (or chemical copper), but is not limited thereto, and the seed layer 125 may include may also include a sputtering layer. The seed layer 125 may include copper (Cu), but is not limited to what is illustrated in FIG. 3. The seed layer 125 may be constituted by a plurality of metal layers. For example, in a case in which the seed layer 125 includes a sputtering layer, the seed layer may further include a metal layer including titanium (Ti). Since the seed layer 125 is formed to be brought into contact with the glass layer 110, in a case in which the seed layer 125 includes a sputtering layer, adhesion to the glass layer 110 can be further secured, but the seed layer 125 is not necessarily limited thereto. Meanwhile, as well as the above-described metal, any material may be used for the seed layer 125 without limitation as long as the material can function as a plating lead-in wire for electroplating. For example, an inorganic carbon-based conductive material or an organic carbon-based conductive material may be used for the seed layer 125.

The seed layer 125 may be conformally disposed along an inner wall of a first through-hole formed in the glass layer 110 and an inner wall of a second through-hole formed in the first insulating layer 111. That is, the seed layer 125 may contact the glass layer 110 and the first insulating layer 111, and may also contact the first wiring layer 121. The seed layer 125 may be disposed on the boundary with the glass layer 110 and extend to the border with the first insulating layer 111 and the border with the first wiring layer 121. In addition, the seed layer 125 may extend upward of the glass layer 110 and may function as a seed layer for the second wiring layer 122.

The plating layer 126 may include an electrolytic plating layer (or electric copper), and may be formed by performing electrolytic plating using the seed layer 125 as a plating lead-in wire. The plating layer 126 may include copper (Cu), but is not limited thereto, and may include the same metal as the first via layer 130. The plating layer 126 may be disposed on the seed layer 125, and may fill the first through-hole penetrating the glass layer 110 and the second through-hole penetrating the first insulating layer 111.

Meanwhile, the forming of the seed layer 125 and the forming of the plating layer 126 may be performed at once, the first via portion 131 and the second via portion 132 of the first via layer 130 may be integrally formed. This means that the boundary between the first via portion 131 and the second via portion 132 of the first via layer 130 may not be confirmed, and the seed layer 125 formed in the first via portion 131 may extend to the second via portion 132, and the plating layer 126 formed in the first via portion 131 may extend to the second via portion 132. Also, the boundary between the plating layer 126 and the seed layer 125 may be confirmed. That is, the integral formation of the first via portion 131 and the second via portion 132 of the first via layer 130 is in contrast to the combination of the first via portion 131 penetrating the glass layer 110 and the second via portion 132 penetrating the first insulating layer 111 after they are formed separately, and means that the first via layer 130 may be formed as one body through a series of processes. At this time, the first via layer 130 and the second wiring layer 122 may be integrally formed. This may be a result of forming the second wiring layer 122 in the forming of the first via layer 130.

The first via portion 131 penetrating the glass layer 110 and the second via portion 132 penetrating the first insulating layer 111 may have different widths. In addition, each of the first via portion 131 and the second via portion 132 may have a width becoming narrower toward the first wiring layer 121 to have a so-called tapered shape.

The widths and shapes of the first via portion 131 and the second via portion 132 of the first via layer 130 may be measured and confirmed by imaging a cross section of the printed circuit board passing cut in the stacking direction through the central axis of the first via layer 130 using a scanning microscope or the like.

At the interface between the first insulating layer 111 and the glass layer 110, the second via portion 132 may have a smaller width than the first via portion 131. The interface between the first insulating layer 111 and the glass layer 110 may be confirmed as a boundary between the first insulating layer 111 and the glass layer 110 in the cross-sectional view, and the widths of the second via portion 132 and the first via portion 131 located on a line extending from this boundary line may be compared. That is, referring to FIG. 3, the width of the second via portion 132 on the uppermost side thereof may be smaller than the width of the first via portion 131 on the lowermost side thereof. This may be a result of forming the second through-hole penetrating the first insulating layer 111 after forming the first through-hole penetrating the glass layer 110 in the method of manufacturing the printed circuit board. After forming the first through-hole penetrating the glass layer 110, the second through-hole penetrating the first insulating layer 111 may be formed to have a smaller width than the first through-hole. However, the first via portion 131 and the second via portion 132 are not necessarily limited thereto, and the width of the second via portion 132 may be substantially the same as the width of the first via portion 131 at the interface between the first insulating layer 111 and the glass layer 110. This means that, at the time of forming the second through-hole penetrating the first insulating layer 111 after forming the first through-hole penetrating the glass layer 110, the glass layer 110 may function as a mask of the second through-hole.

At the interface between the glass layer 110 and the second wiring layer 122, the first via portion 131 may have a smaller width than the second wiring layer 122. This means that when the first via layer 130 and the second wiring layer 122 are formed, the second wiring layer 122 may be formed to have a larger width than the first via layer 130 to function as a land of the first via layer 130. Meanwhile, the width of the first via portion 131 of the first via layer 130 is not smaller than widths of all wires in the second wiring layer 122, and the width of the second wiring layer 122, which is directly connected to the first via layer 130, may be larger than the width of the first via portion 131 of the first via layer 130.

In the cross-sectional view, the first via portion 131 may have a width becoming narrower toward the first wiring layer 121, and the second via portion 132 may have a width becoming narrower toward the first wiring layer 121. The first via portion 131 and the second via portion 132 may have widths that become narrower in substantially the same direction. This is a result of forming the first through-hole penetrating the glass layer 110 and then forming the second through-hole penetrating the first insulating layer 111 in the same direction, after forming the glass layer 110 on the first insulating layer 111. Since the through-holes are formed from the upper side to the lower side based on FIG. 3, each of the first via portion 131 and the second via portion 132 may have a width that is narrower on the lower side than on the upper side.

Meanwhile, it is illustrated in FIG. 3 that each of the first via portion 131 and the second via portion 132 is tapered in a substantially straight line in the cross-sectional view, but is not necessarily limited thereto. Each of a side surface of the first via portion 131 and a side surface of the second via portion 132 may be curved. In addition, it is illustrated in FIG. 3 that the first via portion 131 and the second via portion 132 are tapered at substantially the same inclination, but are not necessarily limited thereto. The first via portion 131 and the second via portion 132 may be tapered to different degrees. That is, the side surfaces of the first via portion 131 and the second via portion 132 may have different slopes in the cross-sectional view. The forming of the first through-hole penetrating the glass layer 110 and the forming of the second through-hole penetrating the first insulating layer 111 may be performed in different processes, and the glass layer 110 and the first insulating layer 111 may be processed to different degrees because the glass layer 110 and the first insulating layer 111 include different materials.

A surface roughness of the glass layer 110 at the interface between the first insulating layer 111 and the glass layer 110 may be smaller than a surface roughness of the glass layer 110 at the interface between the first via layer 130 and the glass layer 110, and may be smaller than a surface roughness of the glass layer 110 at the interface between the second wiring layer 122 and the glass layer 110. That is, referring to FIG. 3, a surface roughness of a lower surface of the glass layer 110 may be smaller than a surface roughness of an upper surface of the glass layer 110, and the surface roughness of the lower surface of the glass layer 110 may be smaller than a surface roughness of an inner side surface of the glass layer 110 in a direction toward the first via layer 130. This may be a result of performing an etching process on the glass layer 110 in the forming of the first through-hole penetrating the glass layer 110. That is, surface roughness may occur on the upper surface and inner side surfaces of the glass layer 110 because the upper surface and inner side surfaces of the glass layer 110 may be processed by etching in the forming of the first through-hole for forming the first via portion 131 of the first via layer 130, and the lower surface of the glass layer 110 may have a lower surface roughness than the upper surface and inner side surfaces of the glass layer 110 because the lower surface of the glass layer 110, which is in contact with the first insulating layer 111, is not etched. When the glass layer 110 is processed and surface roughness is formed on the upper surface and inner side surfaces of the glass layer 110, the adhesion between the first via layer 130 and the glass layer 110 and the adhesion between the second wiring layer 122 and the glass layer 110 can be improved.

The surface roughness of the glass layer 110 may be measured by imaging a cross section of the printed circuit board cut in the stacking direction using a scanning microscope or the like. In order to measure a surface roughness on a cut surface of the glass layer 110, a known surface roughness measurement method such as a center line average calculation method (Ra) or a ten-point average calculation method (Rz) may be considered. However, the surface roughness measurement method is not limited thereto, and any method may be used without limitation as long as the method is capable of measuring a surface roughness. As a non-limiting example, a surface roughness may be measured by marking a mean position of a lower surface of the first wiring layer 121 as an imaginary line, and then obtaining an average of absolute values of height differences with respect to the mean line, or obtaining average of height differences between the five highest points and the five lowest points with respect to the mean line. Meanwhile, the surface roughness measurement method is not limited thereto, but the size comparison will be clearer only if the comparative surfaces of the glass layer 110 are measured using the same method. As a non-limiting example, the lower surface of the glass layer 110 may have a roughness (Ra) value of about 0.1 nm to 0.2 nm, and the upper surface and/or the inner side surface of the glass layer 110 may have a roughness (Ra) value of about 0.4 nm to 0.6 nm. Alternatively, the lower surface of the glass layer 110 may have a roughness (Rz) value of about 1 nm to 3 nm, and the upper surface and/or the inner side surface of the glass layer 110 may have a roughness (Rz) value of about 4 nm to 7 nm.

In the first via layer 130, the first via portion 131 may be deeper than the second via portion 132. That is, the first via portion 131 penetrating the glass layer 110 may be deeper than the second via portion 132 penetrating the first insulating layer 111. This may mean that an insulation distance of the glass layer 110 is larger than an insulation distance of the first insulating layer 111, and may mean that, referring to FIG. 3, a distance between the upper surface and the lower surface of the glass layer 110 is larger than a distance between the upper surface of the first wiring layer 121 and the upper surface of the first insulating layer 111. A thickness of the glass layer 110 may be thicker than a thickness of the first insulating layer 111, but is not necessarily limited thereto. Since the glass layer 110 cannot be formed directly on the first wiring layer 121, the glass layer 110 is formed on the first insulating layer 111 after forming the first insulating layer 111 on the first wiring layer 121. At this time, since the glass layer 110 is formed after forming the first insulating layer 111 thinly, the first via portion 131 penetrating the glass layer 110 can be deeper than the second via portion 132 penetrating the first insulating layer 111.

The depths of the first via portion 131 and the second via portion 132 may be measured by imaging a cross section of the printed circuit board cut in the stacking direction using a scanning microscope or the like. Each of the depths of the first via portion 131 and the second via portion 132 of the first via layer 130 may refer to a vertical distance between the upper and lower surfaces of each of the first via portion 131 and the second via portion 132 of the first via layer 130 in the cross-sectional view. However, the boundary between the first via portion 131 and the second via portion 132 may not be clear because they are integrally formed, and thus, the depth of the first via portion 131 may be understood as a vertical distance between the upper and lower surfaces of the glass layer 110, and the depth of the second via portion 132 may be understood as a vertical distance from the upper surface of the first wiring layer 121 to the upper surface of the first insulating layer 111. That is, among insulation distances between the first wiring layer 121 and the second wiring layer 122, an insulation distance corresponding to the area of the glass layer 110 may be understood as a depth of the first via portion 131, and an insulation distance corresponding to the area of the first insulating layer 111 may be understood as a depth of the second via portion 132.

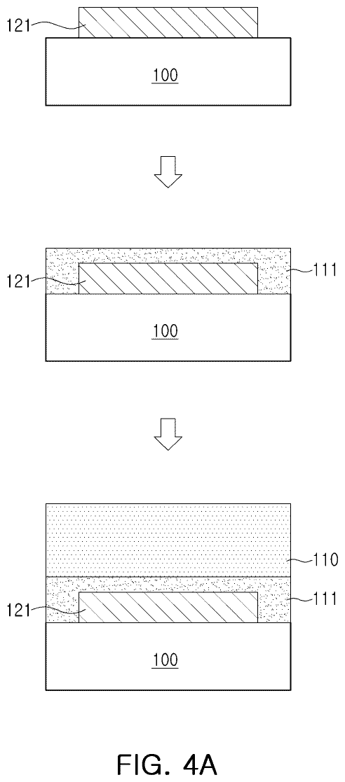

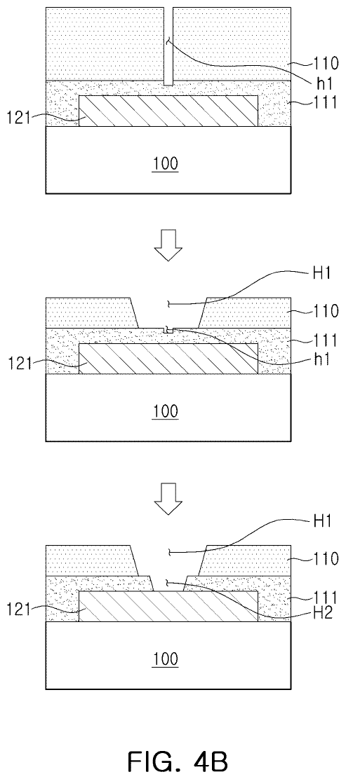

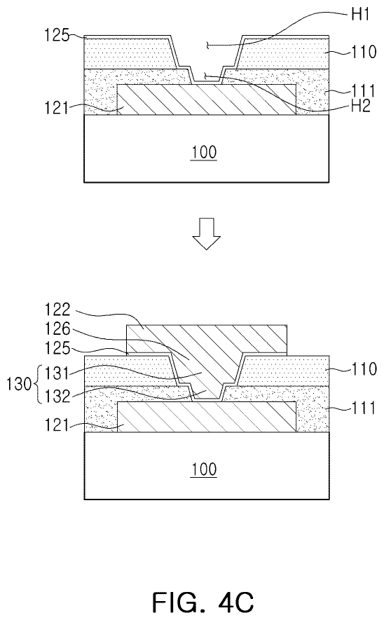

FIGS. 4A to 4C are schematic cross-sectional views illustrating a portion of a method of manufacturing a printed circuit board according to the first exemplary embodiment. The method of manufacturing a printed circuit board includes forming a first insulating layer 111 to embed a first wiring layer 121, forming a glass layer 110 on the first insulating layer 111, forming a first through-hole H1 penetrating at least a portion of the glass layer 110, forming a second through-hole H2 penetrating at least a portion of the first insulating layer 111, forming a first via layer 130 in the first through-hole H1 and the second through-hole H2, and forming a second wiring layer 122 on the first insulating layer 111.

Referring to FIG. 4A, the method of manufacturing a printed circuit board may include forming a first insulating layer 111 and a glass layer 110.

At this time, the first wiring layer 121 may be disposed on an insulating material 100. The insulating material 100 may be an arbitrary component, and the insulating material 100 may be a carrier substrate, a core layer, a build-up insulating layer, or even another glass layer. In a case in which the insulating material 100 is a carrier substrate, the first wiring layer 121 may be located on the outermost side of the coreless structure. In a case in which the insulating material 100 is a core layer, the first wiring layer 121 may be located on the core-type substrate. In a case in which the insulating material 100 is a build-up insulating layer, the first wiring layer 121 may be located in the middle of the build-up of the substrate to have an interlayer structure. In a case in which the insulating material 100 is a glass layer, the same interlayer structure may be repeatedly laminated. That is, in the printed circuit board according to the first exemplary embodiment, the insulating material 100 is expressed as an arbitrary component to express only a portion where the interlayer structure is formed between the first wiring layer 121 and the second wiring layer 122. This means that interlayer structures may be applied in various ways to printed circuit boards according to first to fifth application examples. Meanwhile, the insulating material 100 is not necessarily constituted by only one insulating material, and may have various structures as described above.

Thereafter, the method of manufacturing a printed circuit board may include forming a first insulating layer 111 to embed the first wiring layer 121.

The first insulating layer 111 may be disposed on the insulating material 100 to embed the first wiring layer 121 disposed on the insulating material 100. As a method of forming the first insulating layer 111, a known insulating layer stacking method may be used, and one of various methods may be used depending on the insulating material of the first insulating layer 111. At this time, the first insulating layer 111 may further include a temporary layer such as a protective layer. In a case in which the first insulating layer 111 further includes a temporary layer, the temporary layer may be removed before a glass layer 110 is formed, so the first insulating layer 111 is formed as illustrated in FIG. 4A.

Thereafter, the method of manufacturing a printed circuit board may include forming a glass layer 110 on the first insulating layer 111.

By curing the first insulating layer 111 after forming the glass layer 110 on the first insulating layer 111 before the first insulating layer 111 is cured or in a semi-cured state of the first insulating layer 111, the glass layer 110 may be formed on the first insulating layer 111. After the first insulating layer 111 is formed with a temporary layer included therein, if the temporary layer is removed immediately before the glass layer 110 is formed, the glass layer 110 may be attached to the first insulating layer 111 using the adhesive force of the first insulating layer 111. However, the formation of the glass layer 110 on the first insulating layer 111 is not necessarily limited thereto, and the glass layer 110 may be formed after forming an adhesive means on the first insulating layer 111.

Referring to FIG. 4B, the method of manufacturing a printed circuit board may include forming a first through-hole Hl penetrating the glass layer 110, and forming a second through-hole H2 penetrating the first insulating layer 111.

The forming of the first through-hole Hl penetrating the glass layer 110 may include forming a first hole hl by removing portions of the glass layer 110 and the first insulating layer 111. The first hole hl may be formed using a mechanical processing method. As a non-limiting example, the first hole h1 may be formed by emitting a UV laser. At this time, the UV laser processing may be performed one time, but may also be performed multiple times.

The first hole h1 may be formed to penetrate the glass layer 110, and a portion of the first insulating layer 111 may be processed together in the penetrating of the glass layer 110. That is, the forming of the first hole h1 is performed as a step of penetrating the glass layer 110, and at this time, a portion of the first insulating layer 111 is removed together, so that the first hole h1 may penetrate at least a portion of the first insulating layer 111. It is illustrated in FIG. 4B that the first hole h1 penetrates only a portion of the first insulating layer 111, but is not limited thereto. The first hole h1 may penetrate the first insulating layer 111 to expose a portion of the upper surface of the first wiring layer 121. Meanwhile, the first hole h1 is not limited thereto, and may be formed to penetrate only the glass layer 110 and not to remove the first insulating layer 111. In this case, the first hole h1 may not penetrate a portion of the first insulating layer 111.

Thereafter, a first through-hole H1 may be formed by removing at least a portion of the glass layer 110. The forming of the first through-hole H1 by removing at least a portion of the glass layer 110 may be performed through an etching process. As a non-limiting example, wet etching may be used in the etching process. The removing of at least a portion of the glass layer 110 may be performed by expanding the first hole h1 formed in the glass layer 110 to form the first through-hole H1. That is, the first through-hole H1 can be formed by removing a portion of the glass layer 110 adjacent to the first hole h1. However, the first insulating layer 111 may not be removed in the removing of the glass layer 110, and thus, an area of the first hole h1 formed in the first insulating layer 111 may not be expanded. In the forming of the first through-hole H1, a portion of the upper surface of the first insulating layer 111 may be exposed.

At this time, in a case in which the process is performed by wet etching, a portion of the glass layer 110 may be removed on the upper side thereof, and accordingly, the thickness of the glass layer 110 may be reduced. As a non-limiting example, in a case in which the portion of the glass layer 110 is removed on the upper side thereof, a reduced thickness of the glass layer 110 may correspond to half the diameter of the first through-hole H1. That is, a difference between the thickness of the glass layer 110 before forming the first through-hole H1 and the thickness of the glass layer 110 after forming the first through-hole may correspond to half the width of the first through-hole H1 on the upper side thereof. In the removing of at least a portion of the glass layer 110, surface roughness may occur on an upper surface of the glass layer 110 and an inner side surface of the glass layer 110 constituting a wall surface of the first through-hole H1.

Meanwhile, it is illustrated in FIG. 4B that the first through-hole H1 forms an angle with the upper surface of the glass layer 110, but is not necessarily limited thereto. The first through-hole H1 may be formed to have a curved surface on the upper side thereof. In addition, it is illustrated the first hole h1 forms an angle with the first insulating layer 111, but is not necessarily limited thereto. The first hole h1 may also be formed to have a curved surface, or the first hole h1 may have a conic shape so as not to have a bottom surface.

Meanwhile, it is illustrated in FIG. 4B that the formation of the first through-hole H1 penetrating the glass layer 110 is performed through two steps, but is not necessarily limited thereto. Any via hole processing method for forming a so-called through glass via (TGV), which is a via penetrating the glass layer 110, may be used without limitation. If necessary, the glass layer 110 and the first through-hole H1 may be formed on the first insulating layer 111 by attaching the glass layer 110 through which the first through-hole H1 is formed onto the first insulating layer 111, and any method may be used without limitation as long as the method is capable of forming the first through-hole H1 in the glass layer 110.

Thereafter, a second through-hole H2 penetrating at least a portion of the first insulating layer 111 may be formed. As a method of forming the second through-hole H2, a known method for penetrating the first insulating layer 111 may be used. As a non-limiting example, processing may be performed using a UV laser, a CO₂ laser, or a YAG laser. As the second through-hole H2 is formed, at least a portion of the first wiring layer 121 may be exposed. The second through-hole H2 may be formed to have a larger width than the first hole h1, and thus, the first hole h1 may be included in the second through-hole H2. Meanwhile, after the forming of the second through-hole H2, surface treatment may be performed on the inner side surface of the first insulating layer 111, which forms an inner wall of the second through-hole H2, and a portion of the upper surface of the first insulating layer 111, which forms a bottom surface of the first through-hole H1. The surface treatment may be performed through a desmearing process for removing residues generated in the first insulating layer 111, and additionally, preprocessing for forming the first via layer 130 may be performed.

Referring to FIG. 4C, the method of manufacturing a printed circuit board may include forming a first via layer 130 and forming a second wiring layer 122.

The forming of the first via layer 130 and the forming of the second wiring layer 122 may include forming a seed layer 125. The seed layer 125 may be formed along the inner walls and the bottom surfaces of the first through-hole H1 and the second through-hole H2, and may extend onto the glass layer 110. That is, the seed layer 125 may be formed conformally along the glass layer, the first through-hole H1, and the second through-hole H2. As a method of forming the seed layer 125, a deposition technique such as sputtering may be used, but the method of forming the seed layer 125 is not limited thereto. Since the seed layer 125 extends onto the glass layer 110, in a case in which the sputtering technique is used, adhesion between the seed layer 125 and the glass layer 110 can be more secured, which may be more advantageous in the subsequent plating step. However, the method of forming the seed layer 125 is not limited thereto, and the seed layer 125 may be formed by an electroless plating (or chemical copper) process. In addition, one of various methods may be used depending on the material of the seed layer 125, and the seed layer 125 may be formed using a known method. Thereafter, a plating layer 126 may be formed on the seed layer 125 to form a first via layer 130 and a second wiring layer 122. The forming of the plating layer 126 may be performed by electroplating using the seed layer 125 as a plating lead-in wire. The plating layer 126 may be formed to fill the first through-hole H1 and the second through-hole H2, and the plating layer 126 may form a first via portion 131 and a second via portion 132 of the first via layer 130 together with the seed layer 125 located in the first through-hole H1 and the second through-hole H2, respectively. At this time, since the plating layer 126 is formed by performing plating once to simultaneously fill the second through-hole H2 and the first through-hole H1, the first via portion 131 and the second via portion 132 can be formed in the same step. This is different from the structure in which after a via is formed in the glass layer 110 and a via is formed in the first insulating layer 111, the glass layer 110 and the first insulating layer 111 are coupled to each other by bonding, in that the first via portion 131 penetrating the glass layer 110 and the second via portion 132 penetrating the first insulating layer 111 are integrally formed while the boundary between the first via portion 131 and the second via portion 132 are not unclear. Since the first via portion 131 and the second via portion 132 are integrally formed, it is possible to prevent problems such as separation or misalignment between the first via portion 131 and the second via portion 132.

Meanwhile, the second wiring layer 122 may be formed by forming a plating resist on the seed layer 125, performing plating, removing the plating resist, and then removing a portion of the seed layer 125. However, the formation of the second wiring layer is not necessarily limited thereto, and the second wiring layer 122 may be patterned using a known method, for example, by forming the plating layer 126 on the seed layer 125 and then removing a portion of the plating layer 126 and a portion of the seed layer 125.

In FIGS. 4A to 4C, only the insulating structure of the first insulating layer 111 and the glass layer 110 between the first wiring layer 121 and the second wiring layer 122 and the interlayer connection of the first via layer 130 in the method of manufacturing a printed circuit board according to the first exemplary embodiment are illustrated. As described above, the printed circuit board may have an interlayer structure between the first wiring layer 121 and the second wiring layer 122 at one of various locations. This will be described below in the first to fifth application examples.

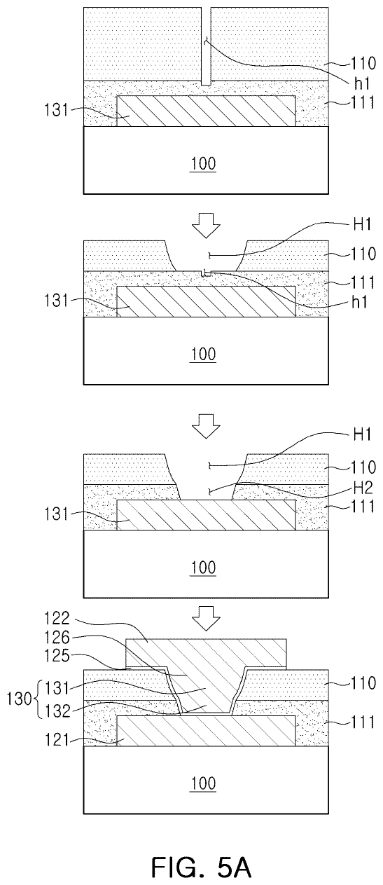

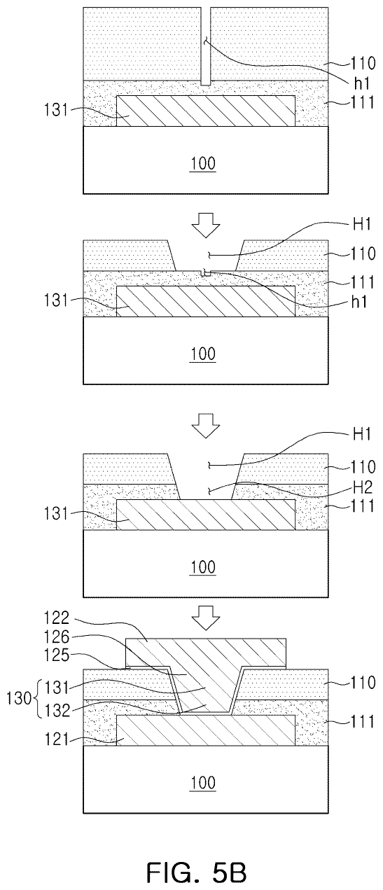

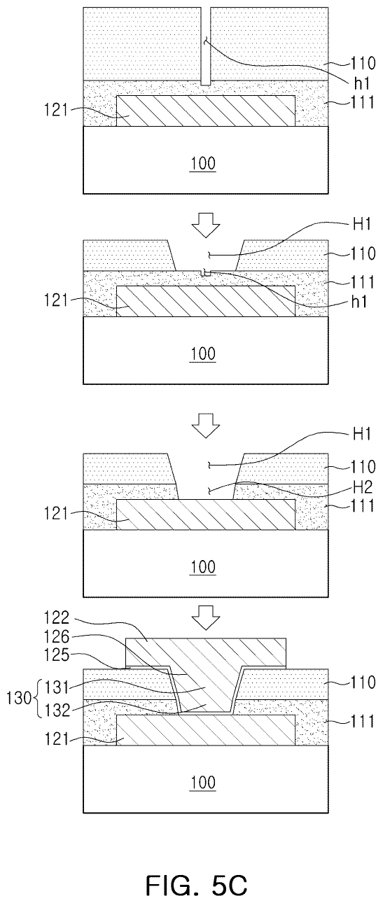

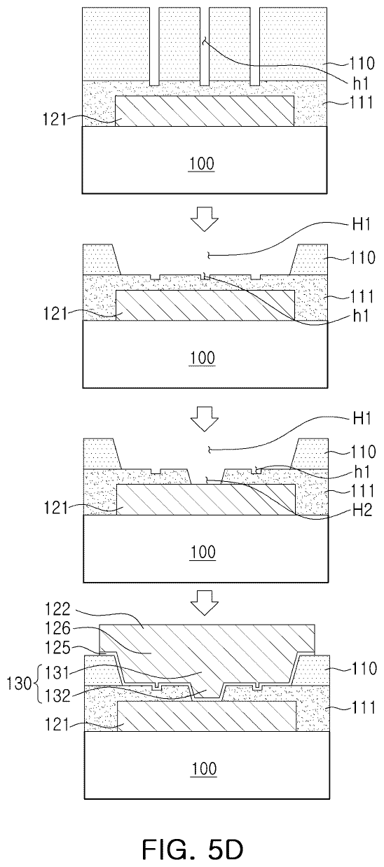

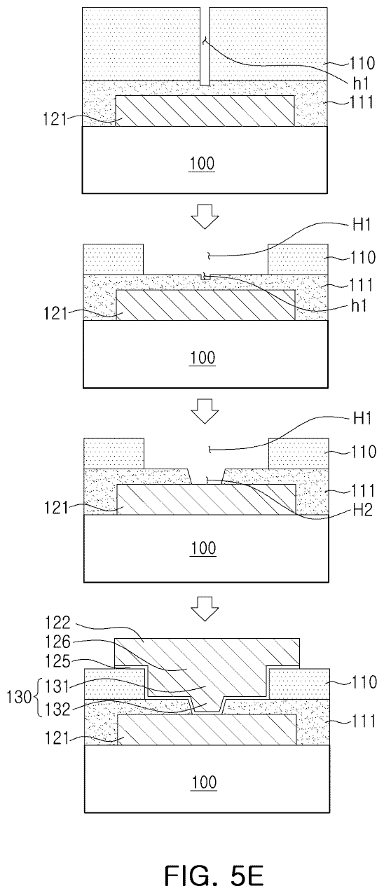

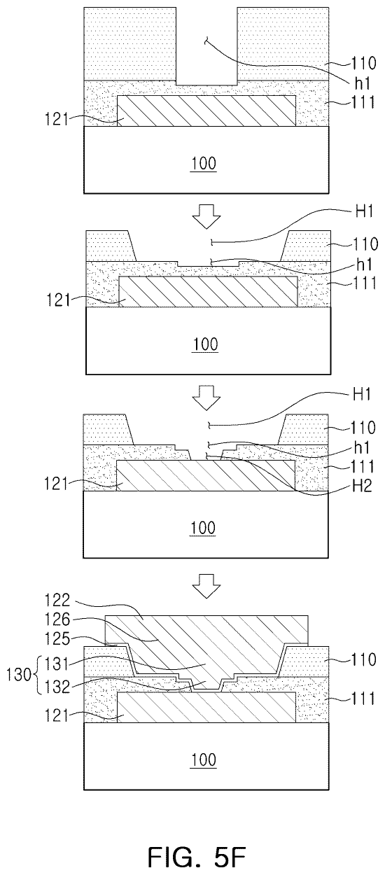

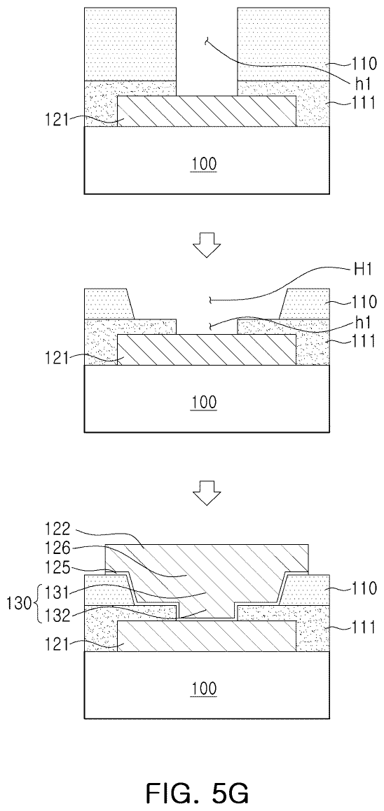

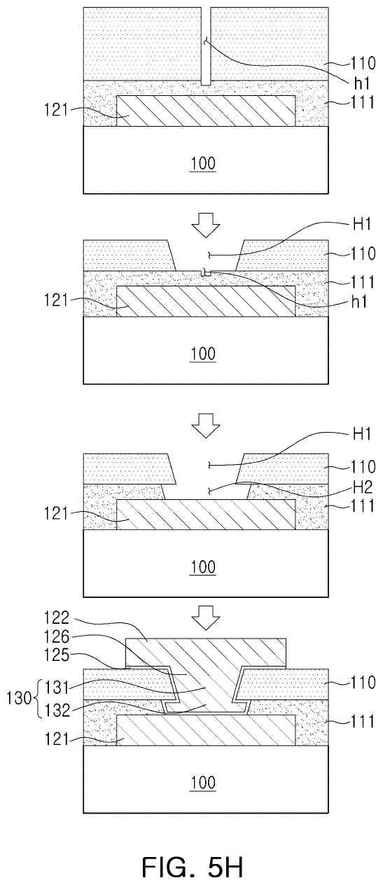

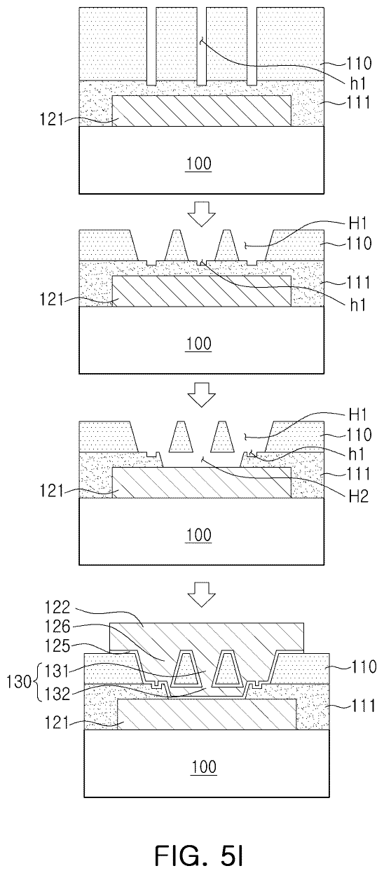

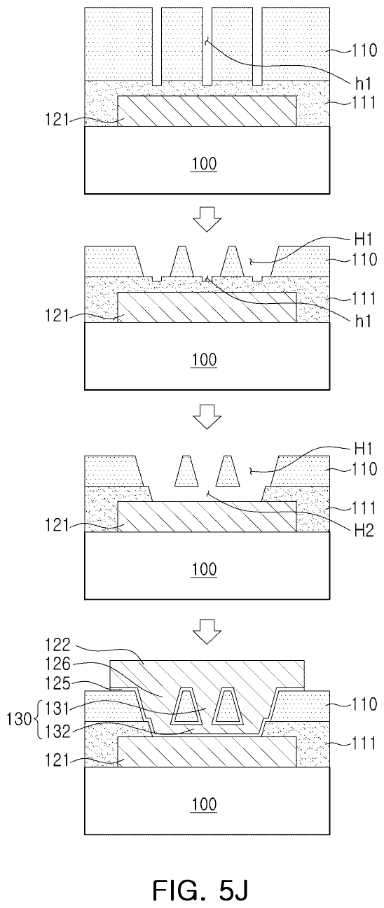

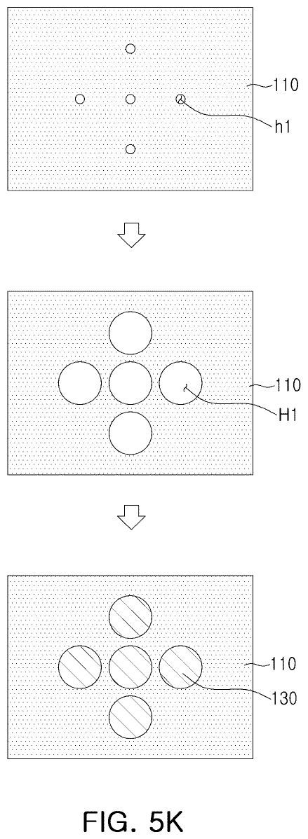

FIGS. 5A to 5J are schematic cross-sectional views illustrating printed circuit boards and parts of methods of manufacturing the same according to first to tenth modifications of the first exemplary embodiment.

FIGS. 5A to 5J illustrate steps after the forming the glass layer 110 in the

method of manufacturing a printed circuit board according to the first exemplary embodiment, and various shapes of the first via layer 130 and manufacturing methods therefor will be mainly described below. In each of FIGS. 5A to 5J, the last step may correspond to a printed circuit board according to each of the first to tenth modifications of the first exemplary embodiment.

Referring to FIG. 5A, in the method of manufacturing a printed circuit board according to the first modification of the first exemplary embodiment, in the forming of the first through-hole H1 by removing at least portion of the glass layer 110, the inner wall of the first through-hole H1 may have a curved surface. In the printed circuit board according to the first modification as well, the inner wall of the first through-hole H1 may have a width that is larger at an upper portion than at a lower portion, and the first through-hole H1 may have a width becoming substantially narrower downward. That is, the first through-hole H1 may have a width becoming substantially narrower toward the first wiring layer 121.

The reason why the inner wall of the first through-hole H1 has a curved surface while the first through-hole H1 has a width becoming substantially narrower is that the portion of the glass layer 110 is removed by etching in the forming of the first through-hole H1. That is, in the forming of the first through-hole H1, a curved surface may occur in a lower area where an etchant is concentrated of the first through-hole H1. However, the formation of the first through-hole H1 is not necessarily limited thereto. In a case in which the etchant is more concentrated on the lower side in the forming of the first through-hole H1, the glass layer 110 may be removed to be wider at the center portion rather than the upper and lower portions of the first through-hole H1. However, even in this case, the first insulating layer 111 may not react to the etchant that removes the glass layer 110, and thus, the first hole h1 formed in the first insulating layer 111 may be maintained in the forming of the first through-hole H1.

Hereafter, in the method of manufacturing a printed circuit board according to the first modification of the first exemplary embodiment, a width of the second through-hole H2 on the upper side thereof may be substantially the same as a width of the first through-hole H1 on the lower side thereof. This is because, in the forming of the second through-hole H2 by removing at least a portion of the first insulating layer 111, the glass layer 110 may function as a mask for the second through-hole H2. That is, the second through-hole H2 may be formed by removing the first insulating layer 111 forming a bottom surface of the first through-hole H1, and as a result, the width of the second through-hole H2 on the upper side thereof may be substantially the same as the width of the first through-hole H1 on the lower side thereof. In this case as well, the second through-hole H2 may be formed using a UV laser, a CO₂ laser, a YAG laser, or the like, and accordingly, the second through-hole H2 may have a tapered shape with a substantially constant amount of change.

In the printed circuit board according to the first modification of the first exemplary embodiment, the side surface of the first via portion 131 may be substantially curved. This may be a result depending on the shape of the first through-hole H1 as described above. In addition, at the interface between the glass layer 110 and the first insulating layer 111, a width of the first via portion 131 may be substantially the same as a width of the second via portion 132. This may be a result depending on the shape of the second through-hole H2. In the printed circuit board according to the first modification of the first exemplary embodiment, since the first via portion 131 of the first via layer 130 may have a substantially curved surface, it is possible to increase a contact area between the glass layer 110 and the first via portion 131, which is more advantageous in improving adhesion. Meanwhile, the shapes of the first via portion 131 and the second via portion 132 are not limited to what are illustrated in FIG. 5A, and the first via portion 131 may have a curved surface of which a radius of curvature varies, such as because the first via portion 131 is not symmetrical, or the first via portion 131 may have a curved surface that is a bumpy surface.

Referring to FIG. 5B, in the method of manufacturing a printed circuit board according to the second modification of the first exemplary embodiment, in the forming of the second through-hole H2 by removing at least a portion of the first insulating layer 111, a width of the second through-hole H2 on the upper side thereof may be substantially the same as a width of the first through-hole H1 on the lower side thereof. This is because, in the forming of the second through-hole H2 by removing at least a portion of the first insulating layer 111, the glass layer 110 may function as a mask for the second through-hole H2. However, the formation of the second through-hole H2 is not necessarily limited thereto, and a separate mask may be used to form the second through-hole H2 to correspond to the width of the bottom surface of the first through-hole H1. That is, since the second through-hole H2 may be formed by removing the first insulating layer 111 that forms the bottom surface of the first through-hole H1, the width of the second through-hole H2 on the upper side thereof may be substantially the same as the width of the first through-hole H1 on the lower side thereof. In this case as well, the second through-hole H2 may be formed using a UV laser, a CO₂ laser, a YAG laser, or the like, and accordingly, the second through-hole H2 may have a tapered shape with a substantially constant amount of change. Meanwhile, the first through-hole H1 and the second through-hole H2 may have a tapered shape with a substantially constant amount of change, but are not necessarily limited thereto.

In the printed circuit board according to the second modification of the first exemplary embodiment, at the boundary between the glass layer 110 and the first insulating layer 111, the width of the first via portion 131 and the width of the second via portion 132 may be substantially the same. This may be a result of forming the second through-hole H2 as described above. At this time, in a case in which the first via portion 131 and the second via portion 132 are formed to have substantially the same slope as illustrated in FIG. 5B, no inflection may occur between the first via portion 131 and the second via portion 132 at the boundary between the glass layer 110 and the first insulating layer 111, and the first via portion 131 and the second via portion 132 may have a tapered shape with a constant inclination, but are not limited thereto.

Referring to FIG. 5C, in the method of manufacturing a printed circuit board according to the third modification of the first exemplary embodiment, in the forming of the second through-hole H2 by removing at least a portion of the first insulating layer 111, a tapered degree of the second through-hole H2 may be different from a tapered degree of the first through-hole H1. As a non-limiting example, an inclination angle formed by the inner wall of the second through-hole H2 and the first wiring layer 121 may be greater than an inclination angle formed by the inner wall of the first through-hole H1 and the first insulating layer 111. That is, the inner wall of the second through-hole H2 may be formed to be closer to the vertical than the inner wall of the first through-hole H1. This may be a result of a difference between the degree to which the glass layer 110 is removed in the forming of the first through-hole Hl by removing at least a portion of the glass layer 110 and the degree to which the first insulating layer 111 is removed in the forming of the second through-hole H2 by removing at least a portion of the first insulating layer 111, or may be a result of a difference in thickness between the glass layer 110 and the first insulating layer 111. The portion of the glass layer 110 may be removed by etching, which is a chemical technique, while the first insulating layer 111 may be removed by a physical technique, and thus, the first insulating layer 111 may be removed to a higher degree and at a higher speed than the glass layer 110. In addition, the first insulating layer 111 may be formed to have a thickness that is substantially smaller than that of the glass layer 110, and thus, the second through-hole H2 formed in the first insulating layer 111 may be tapered to a lower degree than the first through-hole H1 formed in the glass layer 110.

In the printed circuit board according to the third modification of the first exemplary embodiment, at the boundary between the glass layer 110 and the first insulating layer 111, the width of the first via portion 131 may be substantially the same as the width of the second via portion 132, and the inclination angle formed by the side surface of the first via portion 131 and the first insulating layer 111 may be substantially different from the inclination angle formed by the side surface of the second via portion 132 and the first wiring layer 121. More preferably, each of the inclination angle formed by the side surface of the first via portion 131 and the upper surface of the first insulating layer 111 and the inclination angle formed by the side surface of the second via portion 132 and the upper surface of the first wiring layer 121 may be an acute angle, and the inclination angle formed by the side surface of the second via portion 132 and the upper surface of the first wiring layer 121 may be smaller than the inclination angle formed by the side surface of the first via portion 131 and the upper surface of the first insulating layer 111. This may be a result depending on the shape of the first through-hole H1 formed in the glass layer 110 and the shape of the second through-hole H2 formed in the first insulating layer 111. At this time, the inclination angle formed by the two intersecting surfaces may be measured by imaging a cross section of the printed circuit board cut in the stacking direction using a scanning microscope, and may be measured using an angle formed by the actual slope of the via portion and the first insulating layer 111 or the first wiring layer 121 in each of the five arbitrary areas. Meanwhile, any known method for measuring an inclination angle formed by two actual intersecting surfaces, rather than measuring an inclination angle only at one point with respect to an uneven slope, may be used without limitation. Meanwhile, the comparison between inclination angles is not necessarily limited to comparison based on measurements, and may be understood to mean that the second via portion 132 penetrating the first insulating layer 111 has a shape that is substantially closer to the vertical than the first via portion 131 penetrating the glass layer 110.

Referring to FIG. 5D, in the method of manufacturing a printed circuit board according to the fourth modification of the first exemplary embodiment, the forming of the first hole h1 by removing the glass layer 110 and a portion of the first insulating layer 111 may include forming a plurality of first holes h1. That is, a plurality of first holes h1 may be formed to form a first through-hole H1. If the plurality of first holes h1 are formed, it may be easier for the etchant to penetrate and the first through-hole H1 may be formed to be wider in the forming of the first through-hole H1. At this time, areas of the first holes h1 formed in portions of the first insulating layer 111 may not react in the forming of the first through-hole H1, and may not be included in the second through-hole H2 even in the forming of the second through-hole H2 penetrating a portion of the first insulating layer 111. That is, at least some of the first holes h1 may be maintained in both the forming of the first through-hole H1 and the forming of the second through-hole H2, and thus, areas of the first holes h1 formed in at least portions of the first insulating layer 111 remain in the subsequent step of forming the first via layer 130.

In the printed circuit board according to the fourth modification of the first exemplary embodiment, the first via layer 130 may include a groove portion disposed on the lower side of the first via portion 131 and embedded in at least a portion of the first insulating layer 111. The groove portion may be a result of forming the first via layer 130 in an area that remains non-included in the first through-hole H1 and the second through-hole H2 among the plurality of first holes h1. At this time, the seed layer 125 may be conformally disposed along the border of the first hole h1, and the groove portion may be formed by filling the first hole h1 with the plating layer 126 on the seed layer 125. Since the first hole h1 may penetrate only a portion of the first insulating layer 111, rather than entirely penetrating the first insulating layer 111, the groove portion may not be in contact with the first wiring layer 121, and may be disposed to be spaced apart from the second via portion 132 of the first via layer 130 along the perimeter of the second via portion 132. Since the first via layer 130 includes a groove portion, it is possible to increase a contact area between the first via layer 130 and the first insulating layer 111, which is advantageous in securing adhesion.

Referring to FIG. 5E, in the method of manufacturing a printed circuit board according to the fifth modification of the first exemplary embodiment, the first through-hole H1 penetrating the glass layer 110 may be substantially perpendicular to the upper surface of the first insulating layer 111. This may be a result of forming the first through-hole H1 more quickly by controlling an etching degree in the forming of the first through-hole H1 by removing at least a portion of the glass layer 110. Meanwhile, the forming of the first through-hole H1 is not limited thereto, and may be performed through mechanical processing such as laser processing rather than etching. Meanwhile, it is illustrated in FIG. 5E that the inner wall of the first through-hole H1 is substantially perpendicular to the upper and lower surfaces of the glass layer 110 adjoining the first through-hole H1. However, the first through-hole H1 is not limited thereto, and the upper and lower sides of the first through-hole H1 may have curved surfaces, and the inner wall of the first through-hole H1 may be substantially perpendicular to the upper and lower surfaces of the glass layer 110. That is, this means that, in the cross-sectional view, the inner wall portion of the first through-hole H1 may be substantially perpendicular to the upper surface of the first insulating layer 111 and the upper and lower surfaces of the glass layer 110, and means that the inner wall portion of the first through-hole H1 is not tapered with an inclination.

In the printed circuit board according to the fifth modification of the first exemplary embodiment, the first via portion 131 of the first via layer 130 may be substantially perpendicular to the upper surface of the first insulating layer 111, and may be substantially perpendicular to the upper and lower surfaces of the glass layer 110. In addition, the first via portion 131 of the first via layer 130 may be substantially perpendicular to the second wiring layer 122. This may be a result of forming the first via layer 130 after forming the first through-hole H1 so that the first through-hole H1 is substantially perpendicular to the upper surface of the first insulating layer 111 and the upper and lower surfaces of the glass layer 110. At this time, the side surface of the first via layer 130 does not need to form an angle with the upper and lower surfaces of the glass layer 110, and may be curved as described above.

Referring to FIG. 5F, in the method of manufacturing a printed circuit board according to the sixth modification of the first exemplary embodiment, the first hole h1 may be wider than the second through-hole H2. This may be a result of processing a large area by overlapping lasers in the forming of the first hole h1. Since the first hole h1 may be wider than the second through-hole H2 penetrating the first insulating layer 111, the first insulating layer 111 may have a step shape in an area where the first hole h1 and the second through-hole H2 adjoin each other. Thereafter, in the forming of the seed layer 125, the seed layer 125 may be disposed conformally along the borders of the first hole h1 and the second through-hole H2, and the first via layer 130 may be formed by forming a plating layer 126 on the seed layer 125.

In the printed circuit board according to the sixth modification of the first exemplary embodiment, the first via layer 130 may have a recess portion. The recess portion may be disposed on the lower side of the first via portion 131, and may have a step from the upper surface of the first insulating layer 111. The recess portion may be an area corresponding to the first hole h1. Since the first via layer 130 may have a recess portion, it is possible to increase a contact area between the first via layer 130 and the first insulating layer 111, which is advantageous in securing adhesion.

Referring to FIG. 5G, in the method of manufacturing a printed circuit board according to the seventh modification of the first exemplary embodiment, in the forming of the first hole h1, the upper side of the first wiring layer 121 may be exposed by forming the first hole h1 to penetrate the first insulating layer 111. This may be a result of forming the first hole h1 to have a larger area by overlapping lasers or performing processing for forming the first hole h1 for a longer period of time in the forming of the first hole h1. Since the upper side of the first wiring layer 121 is exposed through the first hole h1, the forming of the second through-hole penetrating the first insulating layer 111 can be omitted, thereby reducing one step of the process. At this time, the first hole h1 may be substantially perpendicular to the upper surface of the first insulating layer 111, and may be substantially perpendicular to the first wiring layer 121.

In the printed circuit board according to the seventh modification of the first exemplary embodiment, the second via portion 132 of the first via layer 130 may be substantially perpendicular to the upper surface of the first insulating layer 111, and may be substantially perpendicular to the first wiring layer 121. This may be a result depending on the shape of the first hole h1 in the forming of the first hole h1, and may be a result of omitting the forming of the second through-hole H2.

Referring to FIG. 5H, in the method of manufacturing a printed circuit board according to the eighth modification of the first exemplary embodiment, the second through-hole H2 may be wider than the first through-hole H1. At the interface between the first insulating layer 111 and the glass layer 110, a width of the second through-hole H2 may be larger than a width of the first through-hole H1. This may be a result of processing using a laser such as a UV laser in the forming of the second through-hole H2 penetrating the first insulating layer 111. At this time, as the UV laser, a laser capable of only processing the first insulating layer 111 while being transmitted through the glass layer 110 may be used. In this case as well, a seed layer 125 may be formed conformally along the borders of the first through-hole H1 and the second through-hole H2. Meanwhile, it is illustrated in FIG. 5H that, in the cross-sectional view, the second through-hole H2 is tapered with a substantially constant inclination, but the second through-hole H2 is not necessarily limited thereto, and the side surface of the second through-hole H2 may be curved.

In the printed circuit board according to the eighth modification of the first exemplary embodiment, a width of the second via portion 132 may be larger than a width of the first via portion 131 at the interface between the first insulating layer 111 and the glass layer 110. This results from the shapes of the first through-hole H1 and the second through-hole H2. Since the second via portion 132 penetrating the first insulating layer 111 may be wider than the first via portion 131, the first via layer 130 may have an anchoring effect, and the first via layer 130 may have more improved adhesion.

Referring to FIG. 5I, the method of manufacturing a printed circuit board according to the ninth modification of the first exemplary embodiment may include forming a plurality of first through-holes H1. A plurality of first holes h1 may be formed, and a plurality of first through-holes H1 may be formed to correspond to the plurality of first holes h1, respectively. At this time, the plurality of first holes h1 and the plurality of first through-holes H1 may refer to a plurality of first holes h1 and a plurality of first through-holes H1 connected to one wiring pattern in the first wiring layer 121, rather than a plurality of first holes h1 and a plurality of first through-holes H1 formed in the same layer. A plurality of first through-holes H1 are formed in the glass layer 110, and a second through-hole H2 is formed to penetrate the first insulating layer 111 in such a manner that the plurality of first through-holes H1 are connected to one second through-hole H2 to be connected to one first wiring layer 121. At this time, in the forming of the second through-hole H2, in a case in which a first hole h1 formed in the glass layer 110 and a portion of the first insulating layer 111 is not included in the second through-hole H2, a portion of the first hole h1 may remain in the first insulating layer 111. Thereafter, in the forming of the first via layer 130, a seed layer 125 may be conformally disposed along the respective inner walls of the plurality of first through-holes H1. If first holes h1 remain, the seed layer 125 may also be conformally disposed along the borders of the first holes h1. The plating layer 126 may fill the plurality of first through-holes H1 and the plurality of first holes h1.

In the printed circuit board according to the ninth modification of the first exemplary embodiment, at least one via in the first via layer 130 may include one second via portion 132 and a plurality of first via portions 131, and the plurality of first via portions 131 may be in contact with one second via portion 132 for connection. That is, a plurality of first via portions 131 may be formed to penetrate the glass layer 110, and one second via portion 132 may be formed to penetrate the first insulating layer 111 and connected to the first wiring layer 121. The first via layer 130 may also have a groove portion. The groove portion may have a shape depending on the first hole h1, may be disposed on the lower side of the first via portion 131, and may refer to a portion of the first via layer 130 embedded in the first insulating layer 111. The groove portion may be an area spaced apart from the second via portion. Each of the plurality of first via portions 131 may have a width becoming narrower toward the first wiring layer 121. This may be a result of performing processing from the upper side to the lower side based on FIG. 5F even though the plurality of first through-holes H1 are formed. Since a plurality of first via portions 131 may be formed, it is possible to increase a contact area between the first via layer 130 and the glass layer 110, resulting in a better structure for securing the adhesion of the first via layer 130.

Referring to FIG. 5J, in the method of manufacturing a printed circuit board according to the tenth modification of the first exemplary embodiment, the width of the second through-hole H2 may be adjusted so that the plurality of first holes H1 are included in the second through-hole H2. That is, in the forming of the second through-hole H2 penetrating the first insulating layer 111, the second through-hole may be formed to be connected to the first through-hole H1 by sufficiently securing the width of the second through-hole.

In the printed circuit board according to the tenth modification of the first exemplary embodiment, one second via portion 132 of the first via layer 130 may be connected to the plurality of first via portions 131, and the first via layer 130 may not have a groove portion. This may be a shape depending on the relationship between the first holes h1, the first through-holes H1, and the second through-hole H2. Since the width of the second via portion 132 may be sufficiently secured, sufficient adhesion and connection reliability can be secured between the first via portions 131 and the second via portion 132.

FIG. 5K is plan views illustrating a portion of the method of manufacturing a printed circuit board according to the ninth or tenth modification of the first exemplary embodiment illustrated in FIG. 5I or 5J. Particularly, FIG. 5K relates to the ninth or tenth modification in which a plurality of first holes h1 and a plurality of first through-holes H1 are formed, and may correspond to top plan views of the glass layer 110 when viewed from above.

A plurality of first holes h1 spaced apart from each other may be formed in the glass layer 110, and a plurality of first through-holes H1 may be formed based on the plurality of first holes h1. Thereafter, the plurality of first through-holes H1 may be filled by forming a first via layer 130. In this case, since the upper side of the glass layer 110 does not change in the forming of the second through-hole H2 after the forming of the first through-holes H1, only the top plan views of the glass layer 110 when viewed from above are illustrated, while omitting expressions regarding the forming of the second through-hole H2 and the forming of the second wiring layer 122 on the first via layer 130. Meanwhile, the shape and number of first holes h1 and the shape and number of first through-holes H1 are merely exemplary, and may be modified in various ways.

Meanwhile, in FIGS. 5A to 5J, which relate to various modifications of the printed circuit board and the method of manufacturing the same according to the first exemplary embodiment, only the insulating structure of the first insulating layer 111 and the glass layer 110 between the first wiring layer 121 and the second wiring layer 122 and the interlayer connection of the first via layer 130 are illustrated, and the printed circuit board may have an interlayer structure between the first wiring layer 121 and the second wiring layer 122 at one of various locations.

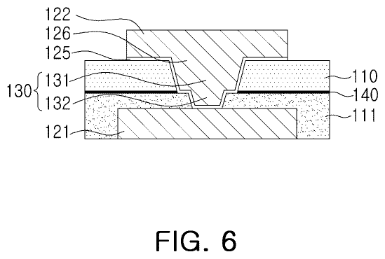

FIG. 6 is a schematic cross-sectional view of a portion of a printed circuit board according to a second exemplary embodiment.

Referring to FIG. 6, the printed circuit board according to the second exemplary embodiment may further include an adhesive layer 140 interposed between the first insulating layer 111 and the glass layer 110. The adhesive layer 140 may improve adhesion between the first insulating layer 111 and the glass layer 110. It is difficult for the glass layer 110 to secure adhesion to another component because a surface of glass is smooth and has a low surface roughness. Therefore, by further including the adhesive layer 140 between the first insulating layer 111 and the glass layer 110, the adhesion between the glass layer 110 and the first insulating layer 111 can be improved. The adhesive layer 140 may include an inorganic oxide film or an organic film.

In a case in which the adhesive layer 140 includes an inorganic oxide film, the adhesive layer 140 may be a thin oxide film including a metal oxide. The metal oxide may include at least one of Al₂O₃, SiO₂, TiO₂, ZnO, ZrO₂, HfO₂, and La₂O₃, but may also include a metal oxide doped with a different metal element. The metal oxide may preferably include alumina (Al₂O₃). In a case in which the adhesive layer 140 includes an inorganic oxide film, the adhesive layer 140 may be formed using a thin film deposition technique, such as an atomic layer deposition (ALD) technique or a molecular vapor deposition (MVD) technique. As the adhesive layer 140 is formed using a thin film deposition technique, the adhesive layer 140 may include an oxide film that is thinner than the first insulating layer 111 and the glass layer 110. As a non-limiting example, the adhesive layer 140 may include a thin oxide film having a thickness of less than 0.1 μm, preferably about 0.001 μm to 0.05 μm.

In a case in which the adhesive layer 140 includes an organic film, the adhesive layer 140 may be a thin organic film including an organic material. As the organic material, a primer resin for adhesion or a promoter for adhesion such as an adhesion promoter (AP) may be used. In a case in which the adhesive layer 140 includes an organic material, the adhesive layer 140 may be formed using a coating method. As a non-limiting example, the material of the adhesive layer 140 may be coated on the first insulating layer 111 by spraying or by dipping, but the coating method is not limited thereto. Any coating method may be used without limitation as long as a thin organic film can be formed on the first insulating layer 111.

Meanwhile, the material of the adhesive layer 140 is not limited thereto, and any other material may be used without limitation as long as the material can be disposed between the first insulating layer 111 and the glass layer 110 for use as a means capable of securing adhesion between the first insulating layer 111 and the glass layer 110.

The first via layer 130 may be disposed to penetrate the adhesive layer 140. More specifically, the first via portion 131 of the first via layer 130 may be disposed to penetrate the adhesive layer 140. That is, an opening of the adhesive layer 140 may have the same width as the first through-hole of the glass layer 110. Meanwhile, the adhesive layer 140 is not necessarily limited thereto, and the opening of the adhesive layer 140 may have the same width as the second through-hole of the first insulating layer 111. In this case, the second via portion 132 of the first via layer 130 may penetrate the adhesive layer 140, and at least a portion of the first via portion 131 of the first via layer 130 may be disposed on the adhesive layer 140. This will be described in more detail in the manufacturing method below.

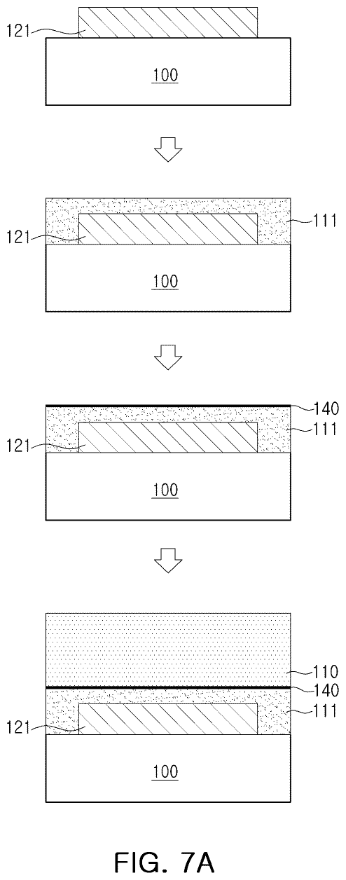

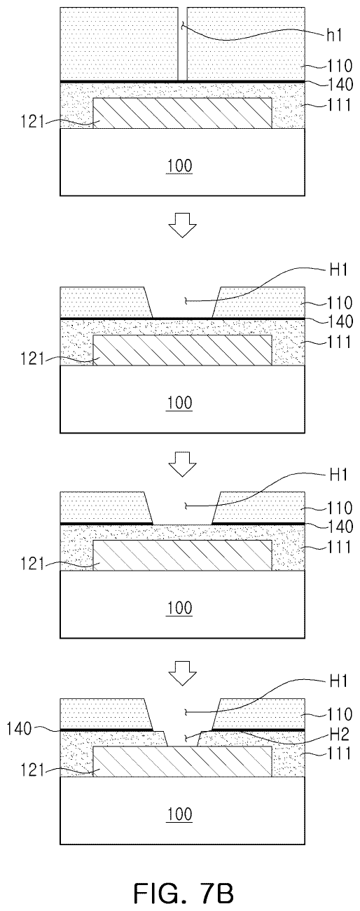

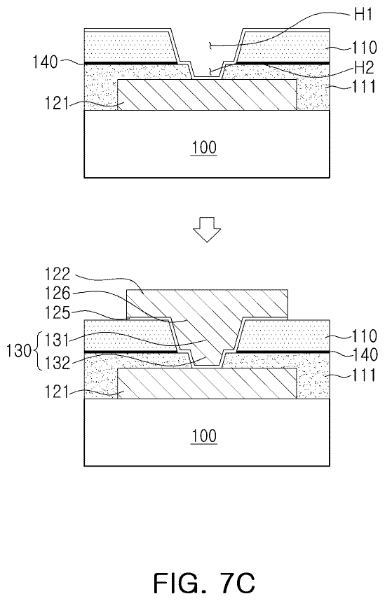

FIGS. 7A to 7C are schematic cross-sectional views illustrating a portion of a method of manufacturing a printed circuit board according to the second exemplary embodiment.

Referring to FIG. 7A, the method of manufacturing a printed circuit board may further include forming an adhesive layer 140 after the forming of the first insulating layer 111. Thereafter, a glass layer 110 may be formed on the adhesive layer. The adhesive layer 140 may be formed using one of various methods depending on the type of the adhesive layer 140, and it is needless to say that a known method may also be used.

Referring to FIG. 7B, in a case in which the adhesive layer 140 includes an inorganic oxide film, the first hole h1 may not penetrate the adhesive layer 140 in the forming of the first hole h1. That is, unlike the case in which the first hole h1 may penetrate a portion of the first insulating layer 111 in the forming of the first hole h1, in a case in which the adhesive layer 140 includes an inorganic oxide film, the adhesive layer 14 may also function as a barrier of the first insulating layer 111.

Thereafter, even in the forming of the first through-hole H1 by removing a portion of the glass layer 110, the adhesive layer 140 may not react.

Thereafter, an opening may be formed in the adhesive layer 140 to correspond to the width of the first through-hole H1. By removing a portion of the adhesive layer 140 exposed through the lower side of the first through-hole H1, the opening may be formed in the adhesive layer 140 and the first insulating layer 111 may be exposed to form a second through-hole H2. As a method of removing the portion of the adhesive layer 140, etching such as dry or wet etching may be used. However, the method of removing the portion of the adhesive layer 140 is not limited thereto, and any method may be used without limitation as long as the adhesive layer 140 can be selectively removed. In the forming of the opening by removing the portion of the adhesive layer 140, the glass layer 110 may not react, and the first insulating layer 111 may also not react. That is, only the adhesive layer 140 may be selectively removed.

Thereafter, the upper side of the first wiring layer 121 may be exposed by forming a second through-hole H2 penetrating the first insulating layer 111. At this time, a portion of the adhesive layer 140 may be removed to correspond to the first through-hole H1, and accordingly, a portion of the upper surface of the first insulating layer 111 may be exposed by the first through-hole H1 and the opening of the adhesive layer 140.

Referring to FIG. 7C, the method of manufacturing a printed circuit board may include forming a first via layer 130 to fill the first through-hole H1 and the second through-hole H2. At this time, a seed layer 125 is conformally disposed along a border of an area exposed by the first through-hole H1 and the second through-hoe H2. Thus, the seed layer 125 may extend to the upper surface of the first insulating layer 111 exposed by the inner wall of the first through-hole H1 and the opening of the adhesive layer 140. As a result, the first via portion 131 of the first via layer 130 may penetrate the adhesive layer 140.

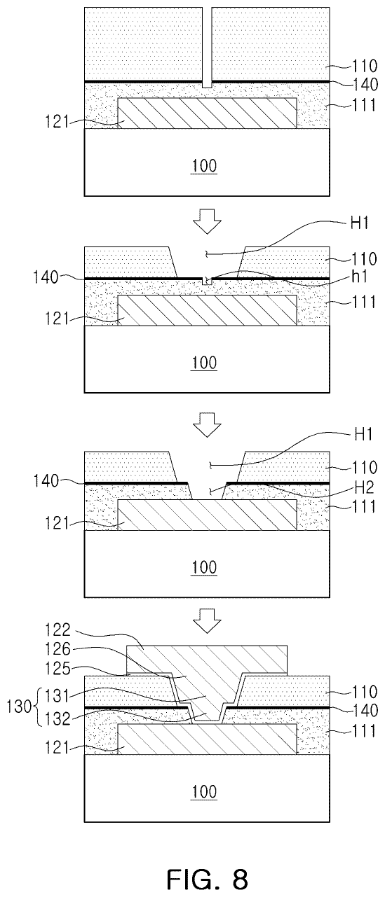

FIG. 8 illustrates schematic cross-sectional views for explaining a printed circuit board and a portion of a method of manufacturing the same according to a first modification of the second exemplary embodiment.

In FIG. 8, steps after the forming of the glass layer 110 in the method of manufacturing a printed circuit board according to the second exemplary embodiment are illustrated, and steps corresponding to FIGS. 7B and 7C are schematically illustrated.

Referring to FIG. 8, in a case in which the adhesive layer 140 includes an organic film, in the forming of the first hole h1, the first hole h1 may penetrate the adhesive layer 140, and at least a portion of the first insulating layer 111 may be removed.

Thereafter, in the forming of the second through-hole penetrating the first insulating layer 111, the adhesive layer 140 may be processed simultaneously with the first insulating layer 111. That is, since both the first insulating layer 111 and the adhesive layer 140 include organic materials, an opening of the adhesive layer 140 may be formed simultaneously in the forming of the second through-hole H2 by performing processing once. As the second through-hole H2 and the opening of the adhesive layer 140 are formed simultaneously, the opening of the adhesive layer 140 may correspond to the second through-hole H2, and the opening may have substantially the same width as the second through-hole H2. At this time, the bottom surface exposed by the first through-hole H1 may be the adhesive layer 140.

Thereafter, by forming a first via layer 130, the first via portion 131 of the first via layer 130 may be formed on the adhesive layer. That is, the second via portion 132 penetrating the first insulating layer 111 may penetrate the adhesive layer 140.

Meanwhile, among the configurations other than the adhesive layer 140, the configurations that are the same as those in the printed circuit boards and the methods of manufacturing the same according to the first exemplary embodiment and the modifications thereof may be applied to the printed circuit board and the method of manufacturing the same according to the second exemplary embodiment, and thus, redundant description thereof will be omitted.

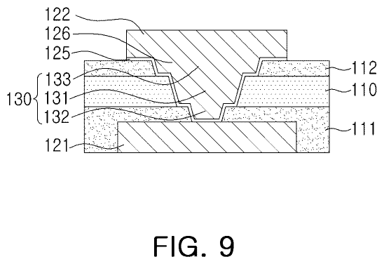

FIG. 9 is a schematic cross-sectional view of a portion of a printed circuit board according to a third exemplary embodiment.

Referring to FIG. 9, the printed circuit board according to the third exemplary embodiment may further include a second insulating layer 112 on the glass layer 110, the second wiring layer 122 may be disposed on the second insulating layer 112, and the first via layer 130 may further have a third via portion 133 penetrating the second insulating layer 112.

The second insulating layer 112 may include an organic insulating material. The organic insulating material may include a thermosetting resin such as an epoxy resin, a thermoplastic resin such as a polyimide, or a material containing an inorganic filler, an organic filler, and/or a glass fiber, a glass cloth or a glass fabric together with the resin. For example, the insulating material may be a non-photosensitive insulating material such as Ajinomoto build-up film (ABF) or prepreg (PPG), but is not limited thereto, and another type of polymer material may be used as an insulating material. Alternatively, the insulating material may be a photosensitive insulating material such as photoimageable dielectric (PID). In addition, the insulating material may include an adhesive sheet such as a bonding sheet (BS). The second insulating layer 112 may include substantially the same insulating material as the first insulating layer 111. Specifically, the second insulating layer 112 may preferably include an Ajinomoto build-up film (ABF), but is not limited thereto, and may include an organic insulating material different from that of the first insulating layer 111. Meanwhile, the second insulating layer 112 is illustrated as one insulating layer in FIG. 9, but is not necessarily limited thereto. If necessary, the second insulating layer 112 may be constituted by a plurality of insulating layers, and may further include a configuration that can be used by those skilled in the art.

As the second insulating layer 112 may be further included on the glass layer 110, the second wiring layer 122 may be disposed on the second insulating layer 112. That is, the second wiring layer 122 may be disposed in contact with the second insulating layer 112. This makes it possible to solve the problem that adhesion between the glass layer 110 and the second wiring layer 122 is relatively low. In this case, even if the seed layer 125 includes an electroless plating layer (or chemical copper), adhesion can be secured on the second insulating layer 112.

The first via layer 130 may further include a third via portion 133 penetrating the second insulating layer 112. The third via portion 133 may be located on the first via portion 131, and all of the first via portion 131, the second via portion 132, and the third via portion 133 may be integrally formed. Also, the third via portion 133 may be integrally formed with the second wiring layer 122.

In the cross-sectional view, each of the first via portion 131, the second via portion 132, and the third via portion 133 may have a width becoming narrower toward the first wiring layer 121. This may be a result of, after stacking the first insulating layer 111, the glass layer 110, and the second insulating layer 112, forming the third through-hole penetrating the second insulating layer 112, the first through-hole penetrating the glass layer 110, and the second through-hole penetrating the first insulating layer 111, and then forming the first via layer 130. That is, since areas where the first via portion 131, the second via portion 132, and the third via portion 133 of the first via layer 130 are to be formed are processed in the same direction to form through-holes, each of the first via portion 131, the second via portion 132, and the third via portion 133 may have a width becoming narrower toward the first wiring layer 121. Meanwhile, it is illustrated in FIG. 9 that each of the first via portion 131, the second via portion 132, and the third via portion 133 is tapered in a substantially straight line in the cross-sectional view, but is not necessarily limited thereto. Each of a side surface of the first via portion 131, a side surface of the second via portion 132, and a side surface of the third via portion 133 may be curved. In addition, it is illustrated in FIG. 9 that the first via portion 131, the second via portion 132, and the third via portion 133 are tapered at substantially the same inclination, but are not necessarily limited thereto. The first via portion 131, the second via portion 132, and the third via portion 133 may be tapered to different degrees. That is, the side surfaces of the first via portion 131, the second via portion 132, and the third via portion 133 may have different slopes in the cross-sectional view. The forming of the first through-hole penetrating the glass layer 110 and the forming of the second through-hole penetrating the first insulating layer 111 may be performed in different processes, and the glass layer 110 and the first insulating layer 111 may be processed to different degrees because the glass layer 110 and the first insulating layer 111 include different materials.

At the interface between the glass layer 110 and the second insulating layer 112, the first via portion 131 may have a smaller width than the third via portion 133. This may be a result of forming the first through-hole penetrating the glass layer 110 after forming the third through-hole H3 penetrating the second insulating layer 112.

The second insulating layer 112 may be thinner than the glass layer 110, but is not necessarily limited thereto. A long insulation distance between the first wiring layer 121 and the second wiring layer 122 may increase an overall thickness of the printed circuit board. Therefore, the second insulating layer 112 may be formed sufficiently thin if the adhesion of the glass layer 110 can be improved. That is, it is preferable that the second insulating layer 112 is formed sufficiently thin if adhesion can be secured between the glass layer 110 and the second insulating layer 112 to the extent that the second insulating layer 112 is not separated from the glass layer 110. Meanwhile, since the second insulating layer 112 is thinner than the glass layer 110, the first via portion 131 may be deeper than the third via portion 133 in the first via layer 130.

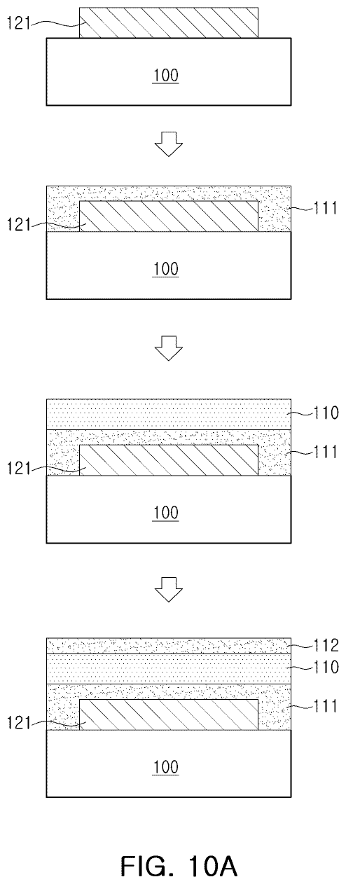

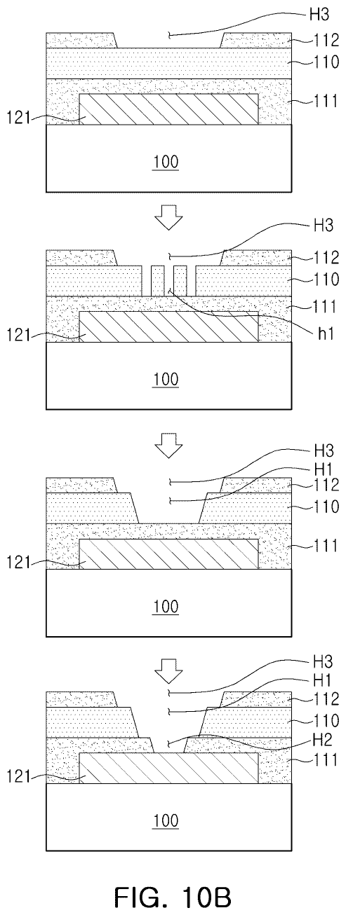

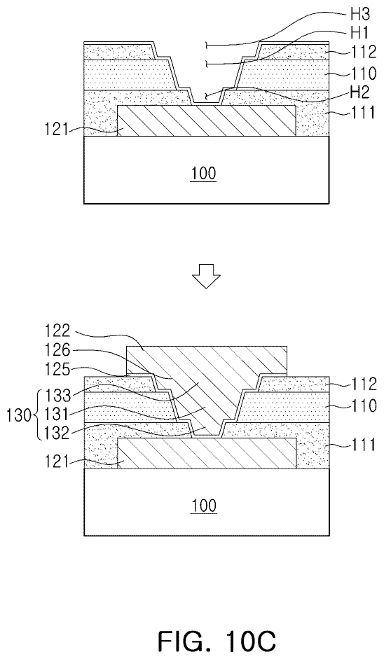

FIGS. 10A to 10C are schematic cross-sectional views illustrating a portion of a method of manufacturing a printed circuit board according to the third exemplary embodiment.

Referring to FIG. 10A, the method of manufacturing a printed circuit board according to the third exemplary embodiment may further include forming a second insulating layer 112 on the glass layer 110 after the forming of the glass layer 110. The second insulating layer 112 may be formed on the glass layer 110 using a known insulating layer stacking method.

Referring to FIG. 10B, before the forming of the first through-hole H1 penetrating the glass layer 110, a third through-hole H3 penetrating the second insulating layer 112 may be formed. The forming of the third through-hole H3 may be performed using a known method for forming a via hole by processing an insulating layer, and may be performed using the same process as the forming of the second through-hole H2 penetrating the first insulating layer 111. At this time, the glass layer 110 may not be damaged even though the third through-hole H3 penetrating the second insulating layer 112 is formed.

Thereafter, a first through-hole H1 penetrating the glass layer 110 may be formed. The forming of the first through-hole H1 may be performed by forming the first hole h1 and forming the first through-hole H1. Meanwhile, in the method of manufacturing a printed circuit board according to the third exemplary embodiment, since the first through-hole H1 penetrating the glass layer 110 is formed after the second insulating layer 112 is formed on the glass layer 110, it is preferable to set etching conditions in the forming of the first through-hole H1 so that the thickness of the glass layer 110 does not decrease. This makes it possible to prevent a decrease in the thickness of the glass layer 110 in the forming of the first through-hole H1.

Meanwhile, it is illustrated in FIG. 10B that the first through-hole H1 is tapered with a substantially constant inclination, but the first through-hole H1 is not necessarily limited thereto, and the inner wall of the first through-hole H1 may be bumpy. In a certain case, a step portion where the etchant is concentrated may be formed in the first through-hole H1.

Thereafter, a second through-hole H2 penetrating the first insulating layer 111 may be formed.

Referring to FIG. 10C, a first via layer 130 may be formed. The first via layer 130 may include a third via portion 133 filling the third through-hole H3, a seed layer 125 may be disposed along the inner wall of the third through-hole H3, and the first via portion 131, the second via portion 132, and the third via portion 133 may be formed simultaneously.

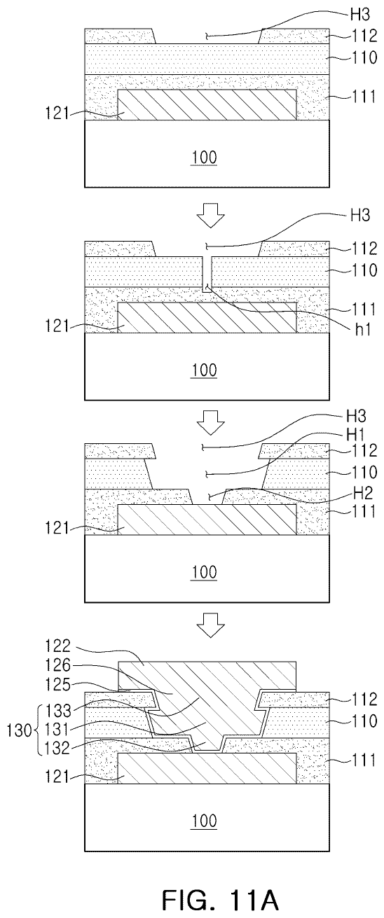

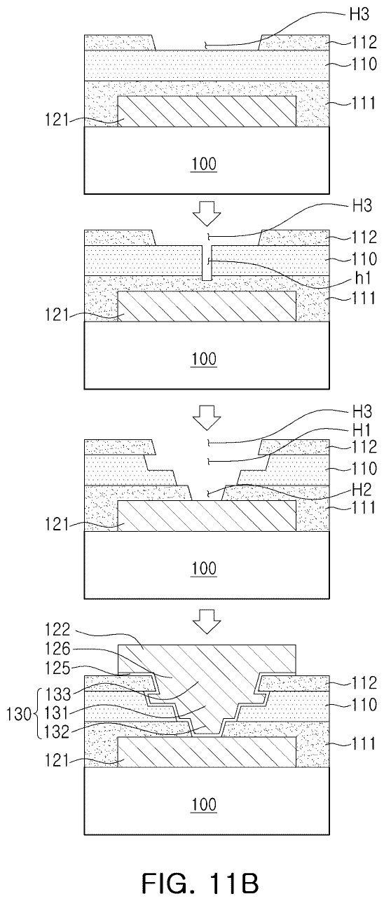

FIGS. 11A and 11B are schematic cross-sectional views illustrating printed circuit boards and parts of methods of manufacturing the same according to first and second modifications of the third exemplary embodiment.

In each of FIGS. 11A and 11B, steps after the forming of the second insulating layer 112 in the method of manufacturing a printed circuit board according to the third exemplary embodiment are illustrated, and various shapes of the first via layer 130 and manufacturing methods therefor will be mainly described below. In each of FIGS. 11A and 11B, the last step may correspond to a printed circuit board according to the first or second modification of the third exemplary embodiment.

Referring to FIG. 11A, in the method of manufacturing a printed circuit board according to the first modification of the third exemplary embodiment, an upper portion of the first through-hole H1 may be wider than a lower portion of the third through-hole H3 in the forming of the first through-hole H1 penetrating the glass layer 110. This may be a result of the etchant entering a portion under the second insulating layer 112 in a case in which wet etching is used in the forming of the first through-hole H1. Since the etchant for removing a portion of the glass layer 110 does not react with the second insulating layer 112, only the glass layer 110 disposed under the second insulating layer 112 can be removed. In this case, the width of the upper portion of the first through-hole H1 may be larger than the width of the lower portion of the third through-hole H3. Thereafter, a second through-hole H2 penetrating the first insulating layer 111 may be formed. Thereafter, a first via layer 130 may be formed. In this case as well, a seed layer 125 may be disposed conformally along the respective inner walls of the through-holes.

In the printed circuit board according to the first modification of the third exemplary embodiment, the first via portion 131 may be wider than the third via portion 133 in the first via layer 130 at the interface between the glass layer 110 and the second insulating layer 112. This may result from the shape of the through-hole created in the forming of the first through-hole H1 penetrating the glass layer 110. As the width of the first via portion 131 of the first via layer 130 increases, it is possible to increase a contact area between the first via layer 130 and the second insulating layer 112, which may be advantageous in securing adhesion.

Referring to FIG. 11B, in the method of manufacturing a printed circuit board according to the second modification of the third exemplary embodiment, the first through-hole H1 may be formed to have a step in the forming of the first through-hole H1 penetrating the glass layer 110. That is, the first through-hole H1 may have a step in the glass layer 110. This may occur in an area where the etchant is concentrated in the forming of the first through-hole H1. In the area where the etchant is concentrated, the glass layer 110 is further removed so as to have a flat surface. Meanwhile, it is illustrated in FIG. 11B that the first through-hole H1 has a flat surface as a step, but the first through-hole H1 is not necessarily limited thereto. The first through-hole H1 may be understood as having an inflection point where the degree of change varies, rather than having a substantially constant change. At this time, it is needless to say that the inner wall of the first through-hole H1 may have a curved surface. Thereafter, a second through-hole H2 penetrating the first insulating layer 111 may be formed. Thereafter, a first via layer 130 may be formed. In this case as well, a seed layer 125 may be disposed conformally along the respective inner walls of the through-holes.

In the printed circuit board according to the second modification of the third exemplary embodiment, the first via portion 131 of the first via layer 130 may have a step between the upper and lower surfaces of the glass layer 110. Not limited thereto, the first via portion 131 of the first via layer 130 may have an inflection portion in the glass layer 110, and may have a curved surface. This may result from the shape of the first through-hole H1 penetrating the glass layer 110 in the above-described method of manufacturing a printed circuit board. As the width of the first via portion 131 of the first via layer 130 increases and a point where the width changes occurs in the first via portion 131 of the first via layer 130, it is possible to increase a contact area between the first via layer 130 and the second insulating layer 112 and a contact area between the first via layer 130 and the glass layer 110, which may be advantageous in securing adhesion.

Meanwhile, among the configurations other than the second insulating layer 112 and the shape of the first via layer 130, the configurations that are the same as those in the printed circuit boards and the methods of manufacturing the same according to the first exemplary embodiment and the modifications thereof and those in the printed circuit boards and the methods of manufacturing the same according to the second exemplary embodiment and the modifications thereof may be applied to the printed circuit board and the method of manufacturing the same according to the third exemplary embodiment, and thus, redundant description thereof will be omitted.

The printed circuit boards and the methods of manufacturing the same according to the first to third exemplary embodiments have been described above, focusing on the insulating structure between the first wiring layer 121 and the second wiring layer 122. Hereinafter, printed circuit boards to which such an insulating structure is applied will be schematically described with reference to the drawings. Although various application examples to which the interlayer structure according to the first exemplary embodiment is applied are illustrated for the purpose of convenience, the application examples are not limited thereto. The interlayer structures according to the second and third exemplary embodiments and the modifications thereof may be applied, and various combinations thereof may also be applied.

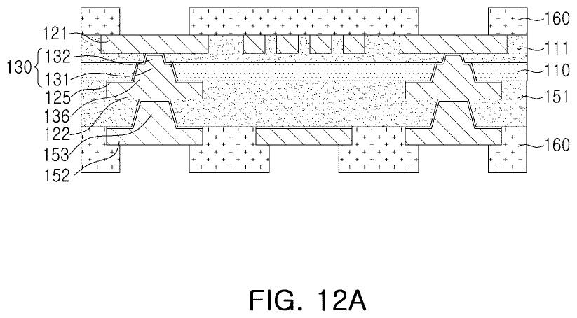

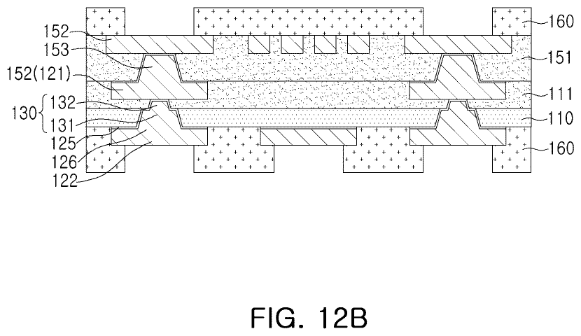

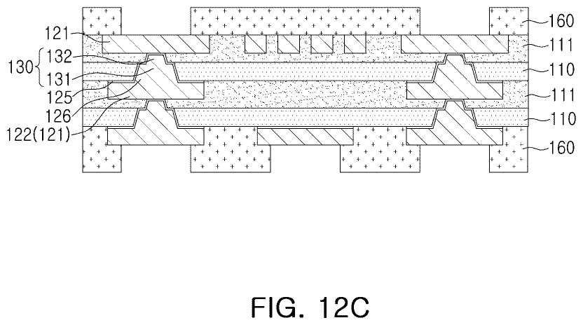

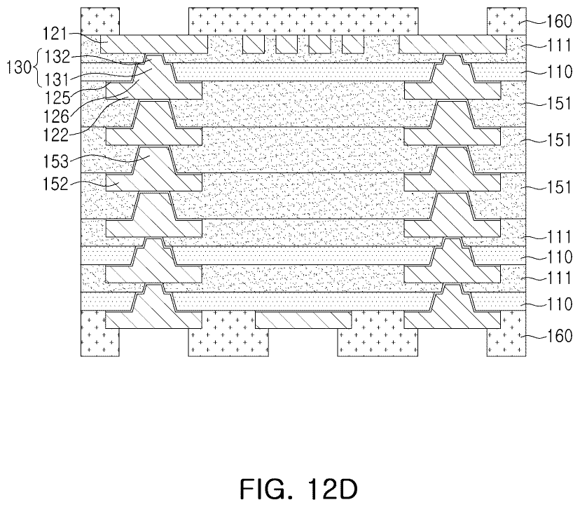

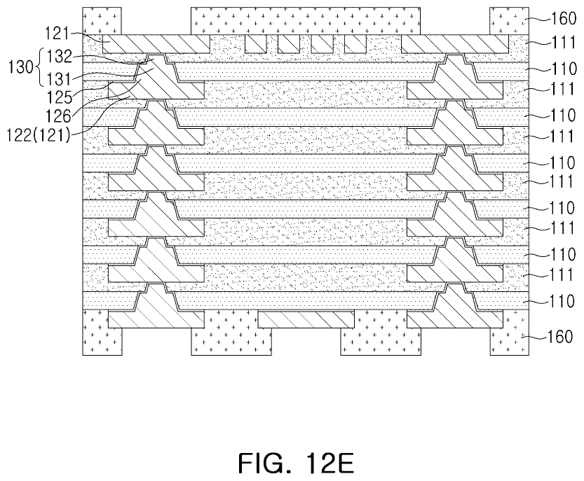

FIGS. 12A to 12E illustrate schematic cross-sectional views of printed circuit boards according to first to fifth application examples of the first exemplary embodiment. Referring to FIGS. 12A to 12E, in each of the first to fifth application examples, the printed circuit board may be a coreless-type printed circuit board. Meanwhile, in each of the first to fifth application examples, the first wiring layer 121 is disposed above the second wiring layer 122, and thus, the direction in the vertical positional relationship is different from that in the first to the third exemplary embodiments. However, this is merely described in a relative manner for convenience, and will be more apparent when understood with reference to the drawings.

Referring to FIG. 12A, the printed circuit board according to the first application example of the first exemplary embodiment may further include a build-up insulating layer 151 disposed on the glass layer 110 and covering at least a portion of the second wiring layer 122, a build-up wiring layer 152 disposed on the build-up insulating layer 151, and a build-up via layer 153 penetrating at least a portion of the build-up insulating layer 151 to connect the build-up wiring layer 152 and the second wiring layer 122 to each other. That is, the printed circuit board according to the first application example of the first exemplary embodiment may further include other build-up layers, as compared with the structure of the printed circuit board according to the first exemplary embodiment.

The build-up insulating layer 151 may include an organic insulating material. The organic insulating material may include a thermosetting resin such as an epoxy resin, a thermoplastic resin such as a polyimide, or a material containing an inorganic filler, an organic filler, and/or a glass fiber, a glass cloth or a glass fabric together with the resin. For example, the insulating material may be a non-photosensitive insulating material such as Ajinomoto build-up film (ABF) or prepreg (PPG), but is not limited thereto, and another type of polymer material may be used as an insulating material. Alternatively, the insulating material may be a photosensitive insulating material such as photoimageable dielectric (PID). In addition, the insulating material may include an adhesive sheet such as a bonding sheet (BS). Specifically, the build-up insulating layer 151 may preferably include an Ajinomoto build-up film (ABF), but is not limited thereto, and may include another organic insulating material. Meanwhile, the build-up insulating layer 151 is illustrated as an insulating layer constituted by one layer in FIG. 12A, but is not necessarily limited thereto. If necessary, the build-up insulating layer 151 may be constituted by a plurality of insulating layers, and may further include a configuration that can be used by those skilled in the art.

The build-up wiring layer 152 may include a metal. The metal may include copper (Cu), aluminum (Al), silver (Ag), tin (Sn), gold (Au), nickel (Ni), lead (Pb), titanium (Ti), and/or alloys thereof. The build-up wiring layer 152 may preferably include copper (Cu), but is not limited thereto. The build-up wiring layer 152 may perform various functions each depending on design. For example, the build-up wiring layer 152 may include a signal pattern, a power pattern, a ground pattern, or the like. Each of these patterns may have various forms such as lines, planes, and pads. The build-up wiring layer 152 may include an electroless plating layer (or chemical copper) and an electrolytic plating layer (or electric copper). Alternatively, the build-up wiring layer 152 may include a metal foil (or a copper foil) and an electrolytic plating layer (or electric copper). Alternatively, the build-up wiring layer 152 may include a metal foil (or a copper foil), an electroless plating layer (or chemical copper), and an electrolytic plating layer (or electric copper). The build-up wiring layer 152 may include a sputtering layer instead of the electroless plating layer (or chemical copper), or the build-up wiring layer 152 may include both a sputtering layer and an electroless plating layer (or chemical copper) if necessary. The build-up wiring layer 152 may be formed using any one technique among a semiadditive process (SAP), a modified semiadditive process (MSAP), a tenting (TT) process, and a subtractive process, but is not limited thereto. Any technique may be used without limitation if the technique is capable of configuring a circuit on a printed circuit board. In addition, the build-up wiring layer 152 may be formed using a different technique depending on the purpose of use and the design.

The build-up via layer 153 may include a micro via. The micro via may be filled via filling a via hole or a conformal via disposed along a wall of a via hole. The micro via may be disposed as a stacked type via and/or a staggered type via. The build-up via layer 153 may include a metal, and the metal may include copper (Cu), aluminum (Al), silver (Ag), tin (Sn), gold (Au), nickel (Ni), lead (Pb), titanium (Ti), or alloys thereof, and preferably copper (Cu), but is not limited thereto. The build-up via layer 153 may preferably include copper (Cu), but is not limited thereto. The build-up via layer 153 may include an electroless plating layer (or chemical copper) and an electrolytic plating layer (or electric copper), but is not limited thereto. The build-up via layer 153 may include a sputtering layer instead of the electroless plating layer, or the build-up via layer 153 may include both a sputtering layer and an electroless plating layer if necessary. The build-up via layer 153 may perform various functions each depending on design. For example, the build-up via layer 153 may include a ground via, a power via, a signal via, or the like.

Meanwhile, in the printed circuit board according to the first application example of the first exemplary embodiment, the first wiring layer 121 and the first insulating layer 111 may be located on the outermost side of the printed circuit board. That is, the first wiring layer 121 may function as a connection pad of the printed circuit board, and may perform a function for connection with an electronic component or the like mounted on the printed circuit board.

The printed circuit board according to the first application example of the first exemplary embodiment may include a solder resist layer 160 disposed on the first insulating layer 111 and covering at least a portion of the first wiring layer 121. The solder resist layer 160 may be disposed on the outermost side of the printed circuit board to function to protect the printed circuit board. The solder resist layer 160 may be disposed on the first insulating layer 111, which is the uppermost side based on FIG. 12A, and may also be disposed on the build-up insulating layer 151, which is the lowermost side based on FIG. 12A. The solder resist layer 160 may include an insulating material, and may include a liquid or film-type solder resist, but is not limited thereto, and any other type of insulating material may be used. The solder resist layer 160 at the uppermost side may have an opening exposing at least a portion of the first wiring layer 121, and the solder resist layer 160 at the lowermost side may have an opening exposing at least a portion of the build-up wiring layer 152.

Referring to FIG. 12B, in the printed circuit board according to the second application example of the first exemplary embodiment, the first wiring layer 121 may be disposed on the build-up insulating layer 151, and the first insulating layer 111 may be disposed on the build-up insulating layer 151. That is, a printed circuit board may be configured by disposing the structure of the printed circuit board according to the first exemplary embodiment on another build-up layer.

The printed circuit board according to the second application example of the first exemplary embodiment may further include a build-up insulating layer 151 disposed on one side of the first insulating layer 111, a build-up wiring layer 152 embedded in the build-up insulating layer 151 on one side thereof, and a build-up via layer 153 penetrating at least a portion of the build-up insulating layer 151 to connect the build-up wiring layer 152 and the first wiring layer 121 to each other.

Referring to FIG. 12C, the printed circuit board according to the third application example of the first exemplary embodiment may have a structure in which the first insulating layers 111 are repeatedly disposed on the glass layer 110. That is, a printed circuit board may be configured by repeating the interlayer structure of the printed circuit board according to the first exemplary embodiment. In this case, the second wiring layer 122 may be disposed as a first wiring layer 121 of a next structure. At this time, the first insulating layer 111 may be disposed on the glass layer 110. In addition, the second wiring layer 122 may also be disposed on the outermost side of the printed circuit board. That is, the solder resist layer 160 may also be disposed on the glass layer 110.

Referring to FIG. 12D, the printed circuit board according to the fourth application example of the first exemplary embodiment may have a structure in which the interlayer structure and the build-up structure are combined. In other words, in the interlayer structure according to the first exemplary embodiment, which is a form of build-up structure, the insulating structure constituted by only an insulating layer may be replaced with the insulating structure including the first insulating layer 111 and the glass layer 110. However, in this case as well, considering the stacking direction of the coreless-type printed circuit board, it may be more preferable, in controlling the flatness and bending characteristics of the printed circuit board, to apply the interlayer structure according to the first exemplary embodiment to the uppermost side based on FIG. 12D.

Referring to FIG. 12E, the printed circuit board according to the fifth application example of the first exemplary embodiment may have a structure in which a coreless-type printed circuit board is configured only with the interlayer structure according to the first exemplary embodiment.

Meanwhile, FIGS. 12A to 12E are merely examples illustrating how the interlayer structure according to the first exemplary embodiment may be applied to other interlayer structures, and the number of insulating layers and the number of wiring layers may be freely modified, and the wiring pattern of the wiring layer may also be modified in various ways. In addition, the printed circuit boards according to the first to fifth application examples are not limited to the configurations illustrated in FIGS. 12A to 12E, and other configurations may further be included, or any of the configurations illustrated in FIGS. 12A to 12E may be omitted in a certain case. That is, the printed circuit board may further include configurations that can be used by those skilled in the art.

As a non-limiting example, the printed circuit board according to any one of the first to fifth application examples may further include a surface treatment layer disposed on the wiring layer exposed by the opening of the solder resist layer 160. The surface treatment layer may include any one of nickel (Ni), palladium (Pd), and gold (Au), and may be implemented by a plurality of metal layers. For example, the surface treatment layer may be at least a portion of an electroless nickel electroless palladium immersion gold (ENEPIG) structure, or at least a portion of an electroless nickel immersion gold (ENIG) structure. The surface treatment layer is not limited thereto, and may include an organic solder passivation (OSP) structure containing organic materials. The surface treatment layer can improve adhesion and signal transmission between the wiring layer and the connection means such as solder.

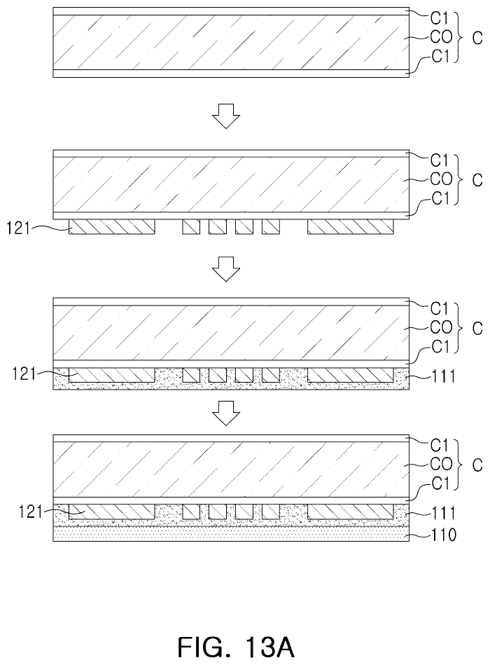

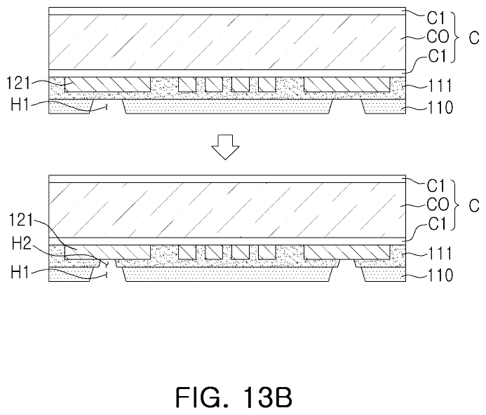

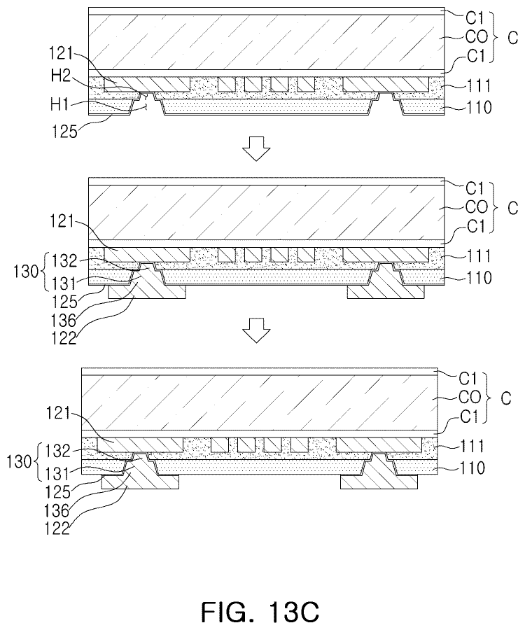

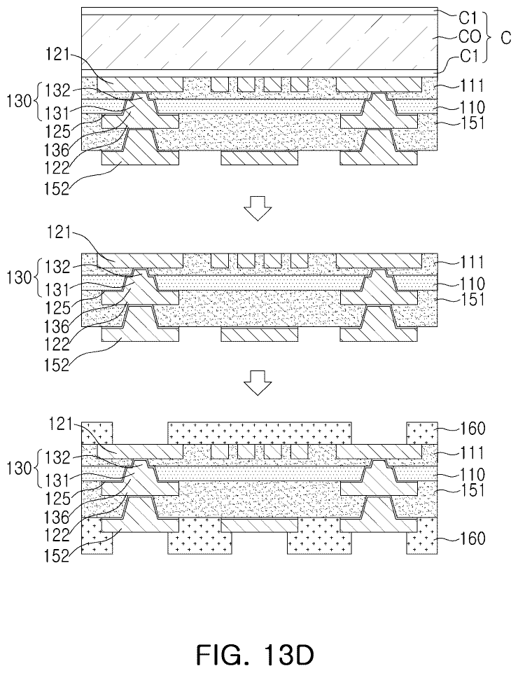

FIGS. 13A to 13D are schematic cross-sectional views illustrating a method of manufacturing the printed circuit board according to the first application example of the first exemplary embodiment illustrated in FIG. 12A.

Referring to FIG. 13A, the method may further include forming a first wiring layer 121 on a carrier substrate C before the forming of the first insulating layer 111.

The carrier substrate C, which serves to support an insulating layer and a wiring layer at the time of forming them, and may be formed of an insulating material or a metal material. It is illustrated in FIG. 13A that the carrier substrate C includes a core CO and seeds C1 formed on both sides of the core CO, but the carrier substrate C is not limited thereto, and the carrier substrate C may be formed as a single layer, or the seed C1 may be formed as a double layer. That is, although one example of carrier substrate C is illustrated, any carrier substrate C may be used in the present disclosure without particular limitation as long as the carrier substrate C can be used by those skilled in the art and can be detached or removed after being used as a support substrate. As a non-limiting example, a stopper layer including a different metal layer may be further formed on the carrier substrate C.

The first wiring layer 121 may be formed on the carrier substrate C, and the first insulating layer 111 may also be disposed on the carrier substrate C to embed the first wiring layer 121. That is, it may be understood, in the method of manufacturing a printed circuit board according to the first exemplary embodiment described with reference to FIGS. 4A to 4C, that the insulating material 100 corresponds to the carrier substrate C.

FIGS. 13B and 13C may be substantially the same as the method of forming the interlayer structure of the printed circuit board according to the first exemplary embodiment, and thus, detailed description thereof will be omitted. Meanwhile, the forming of the through-holes penetrating the glass layer 110 and the first insulating layer 111 is briefly expressed, and detailed information about this may be replaced with the description about the printed circuit board and the method of manufacturing the printed circuit board according to the first exemplary embodiment.

Referring to FIG. 13D, the method may include forming a build-up insulating layer 151, a build-up wiring layer 152, and a build-up via layer 153 on the glass layer 110, removing the carrier substrate C, and forming a solder resist layer 160.

The build-up insulating layer 151 may be formed on the glass layer 110 using a known build-up layer stacking method, and the build-up wiring layer 152 and the build-up via layer 153 may be formed using any method for building up an insulating layer and a wiring layer that can be used by those skilled in the art.

The carrier substrate C may be removed by applying one of various methods depending on the shape of the carrier substrate C. For example, in the removing of the carrier substrate C, the seeds may be removed sequentially after removing the core included in the carrier substrate, or the carrier substrate may be removed integrally, that is, the core and the copper foils may be removed simultaneously. The carrier substrate C may be removed using a known process used for detaching a carrier without limitation.

Meanwhile, although not illustrated in FIG. 13D, a portion of the first wiring layer 121 may be removed together in the removing of the carrier substrate C, and a so-called recess, where a step occurs, may be formed between the first wiring layer 121 and the first insulating layer 111. This may be a result of removing a portion of the first wiring layer 121 when the seeds C1 of the carrier substrate C are removed by an etchant.

After removing the carrier substrate C, the method may include forming a solder resist layer 160 on each of the first insulating layer 111 and the build-up insulating layer 151. The solder resist layer 160 may be formed using any method for building up an insulating layer and a wiring layer that can be used by those skilled in the art.

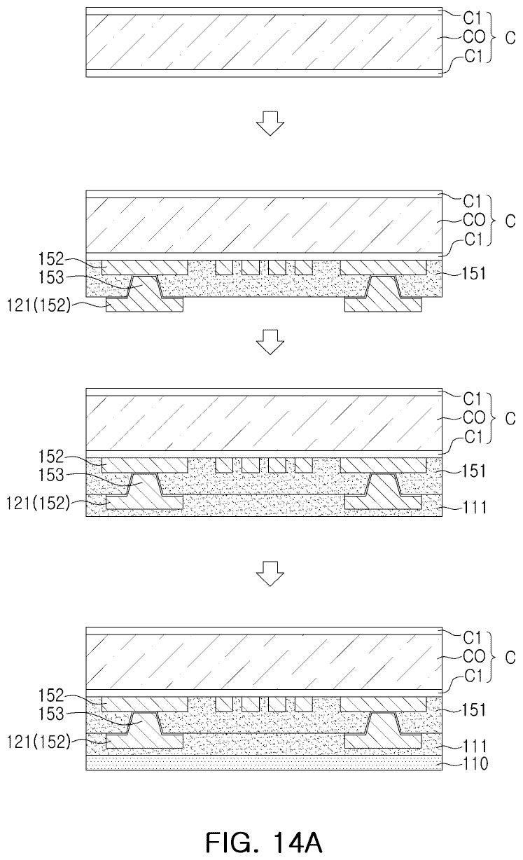

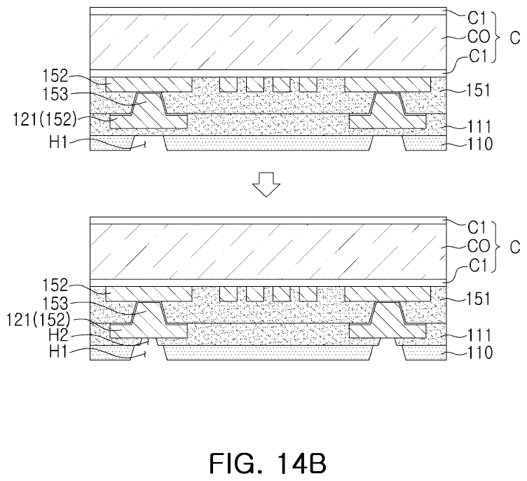

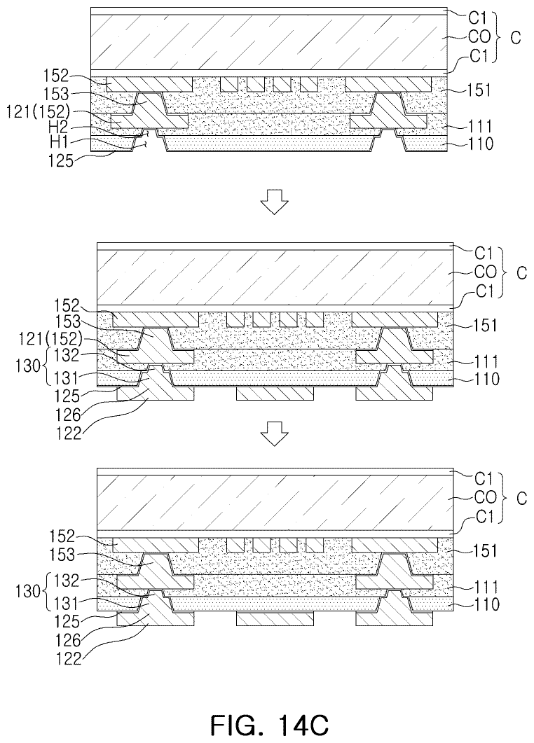

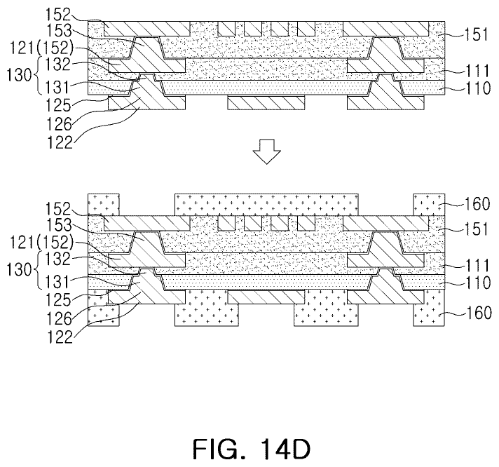

FIGS. 14A to 14D are schematic cross-sectional views illustrating a method of manufacturing the printed circuit board according to the second application example of the first exemplary embodiment illustrated in FIG. 12B.

Referring to FIG. 14A, the method of manufacturing the printed circuit board according to the second application example of the first exemplary embodiment includes forming a build-up insulating layer 151, a build-up wiring layer 152, and a build-up via layer 153 on the carrier substrate C. Thereafter, the method may include forming a first insulating layer 111 on the build-up insulating layer 151. At this time, the build-up insulating layer 151 may have an interlayer structure as a first wiring layer 121. That is, it may be understood, in the method of manufacturing a printed circuit board according to the first exemplary embodiment described with reference to FIGS. 4A to 4C, that the insulating material 100 corresponds to the build-up insulating layer 151.

The other configurations in FIGS. 14A to 14C may be substantially the same as those in the method of forming the interlayer structure of the printed circuit board according to the first exemplary embodiment, and thus, detailed description thereof will be omitted. Meanwhile, the forming of the through-holes penetrating the glass layer 110 and the first insulating layer 111 is briefly expressed, and detailed information about this may be replaced with the description about the printed circuit board and the method of manufacturing the printed circuit board according to the first exemplary embodiment as described above.

Referring to FIG. 14D, the method may further include removing the carrier substrate C and forming a solder resist layer 160, which may be performed in substantially the same manner as described in the first application example, and thus, redundant description thereof will be omitted.

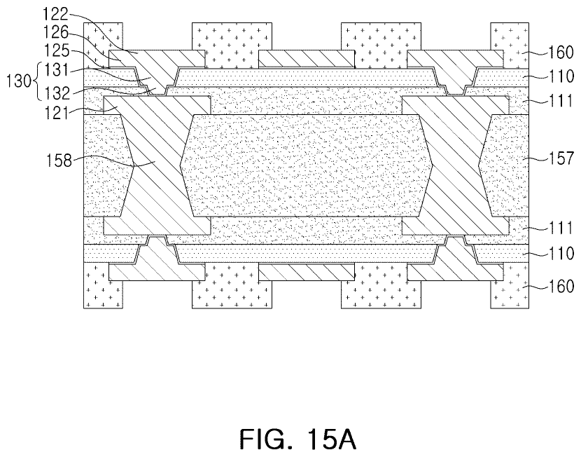

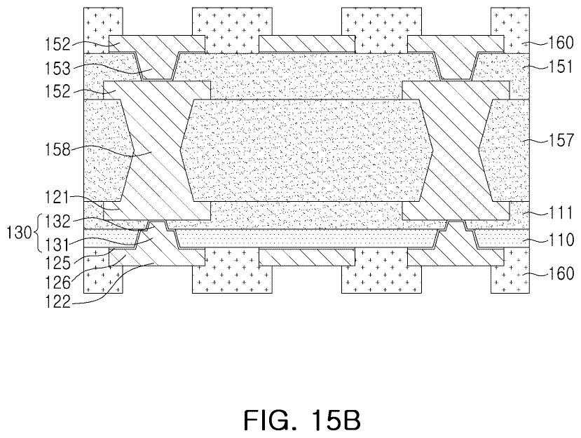

FIGS. 15A and 15B illustrate schematic cross-sectional views of printed circuit boards according to sixth and seventh application examples of the first exemplary embodiment.

Referring to FIGS. 15A and 15B, in each of the sixth and seventh application examples, the printed circuit board may be a cored-type printed circuit board. Meanwhile, in each of the sixth and seventh application examples, layers are stacked upward and downward from a core layer 157, and thus, the direction in the vertical positional relationship is different from that in the first to the third exemplary embodiments. However, this is merely described in a relative manner for convenience, and will be more apparent when understood with reference to the drawings.

Referring to FIG. 15A, the printed circuit board according to the sixth application example of the first exemplary embodiment may include a core layer 157 disposed on one side of the first insulating layer 111 and a through via 158 penetrating the core layer 157. The core layer 157 may include an insulating material. The insulating material may include a thermosetting resin such as an epoxy resin, a thermoplastic resin such as a polyimide, or a material containing an inorganic filler, an organic filler, and/or a glass fiber, a glass cloth or a glass fabric together with the resin. The insulating material may be a photosensitive material and/or a non-photosensitive material. As the insulating material, solder resist (SR), Ajinomoto build-up film (ABF), FR-4, bismaleimide triazine (BT), resin coated copper (RCC), copper clad laminate (CCL), or the like may be used. However, the insulating material is not limited thereto, and another type of polymer material may be used as an insulating material. Meanwhile, the resin in which an inorganic filler such as silica and a reinforcing material such as glass fiber are included may also be used, but the insulating material is not limited thereto. For example, prepreg may be used, but the insulating material is not limited thereto. Meanwhile, as a non-limiting example, the core layer 157 may include a glass substrate, and the material constituting the core layer 157 may not be limited.

The through via 158 may include a metal layer formed on a wall of a through-hole penetrating the core layer 157 and a plug filling the metal layer. The metal layer may include copper (Cu), aluminum (Al), silver (Ag), tin (Sn), gold (Au), nickel (Ni), lead (Pb), titanium (Ti), or alloys thereof, and may preferably include copper (Cu), but is not limited thereto. The plug may include ink as an insulating material. The metal layer may include an electroless plating layer (or chemical copper) and an electrolytic plating layer (or electric copper), but is not limited thereto. The metal layer may include a sputtering layer instead of the electroless plating layer, or the metal layer may include both a sputtering layer and an electroless plating layer. The through via 158 may perform various functions each depending on design. For example, the through via 158 may include a ground via, a power via, a signal via, or the like.

In the printed circuit board according to the sixth application example of the first exemplary embodiment, the wiring layer contacting the core layer 157 may be positioned as a first wiring layer 121, and the interlayer structure according to the first exemplary embodiment may be applied onto the core layer 157. Meanwhile, it is illustrated in FIG. 15A that the interlayer structure according to the first exemplary embodiment is disposed on the outermost side of the printed circuit board, but the interlayer structure according to the first exemplary embodiment is not limited thereto. It is needless to say that another build-up insulating layer and another build-up wiring layer may be further disposed on the glass layer 110.

Referring to FIG. 15B, the printed circuit board according to the seventh application example of the first exemplary embodiment may have an asymmetric substrate structure that is not symmetrical with respect to the core layer 157. Build-up layers including a build-up insulating layer 151, a build-up wiring layer 152, and a build-up via layer 153 may be stacked on the upper side of the core layer 157, and the interlayer structure of the printed circuit board according to the first exemplary embodiment may be applied onto the lower side of the core layer. That is, the interlayer structure according to the first exemplary embodiment may be disposed on one side of the core layer 157, build-up layers may be disposed on the other side of the core layer 157, and the interlayer structure according to the first exemplary embodiment and the build-up layers may be connected to each other by through vias. Since the printed circuit board according to the first exemplary embodiment includes a glass layer 110 in the interlayer structure, flatness and warpage characteristics can be improved, and accordingly, warpage can be suppressed even if an asymmetric substrate is implemented.

Meanwhile, FIGS. 15A and 15B are merely examples illustrating how the interlayer structure according to the first exemplary embodiment may be applied to other interlayer structures, and the number of insulating layers and the number of wiring layers may be freely modified, and the wiring pattern of the wiring layer may also be modified in various ways. In addition, the printed circuit boards according to the sixth and seventh application examples are not limited to the configurations illustrated in FIGS. 15A and 15B, and other configurations may further be included, or any of the configurations illustrated in FIGS. 15A and 15B may be omitted in a certain case. That is, the printed circuit board may further include configurations that can be used by those skilled in the art. It is needless to say that each of the printed circuit boards according to the sixth and seventh application examples may also further include a surface treatment layer on the wiring layer exposed by the opening of the solder resist layer 160.

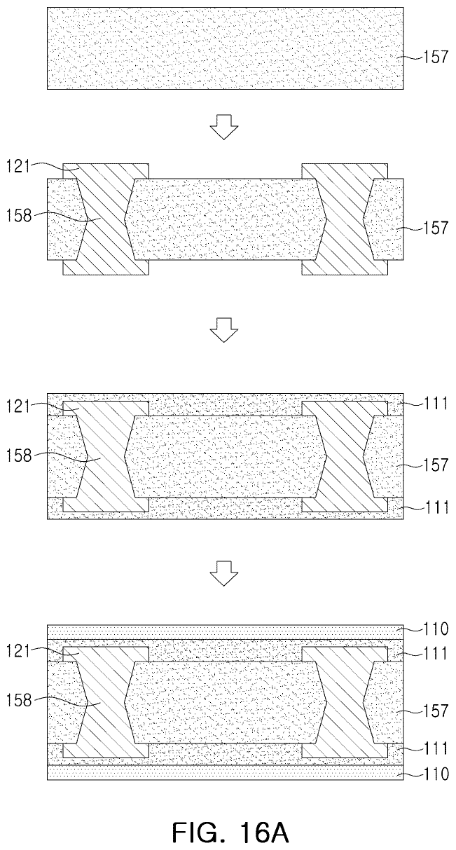

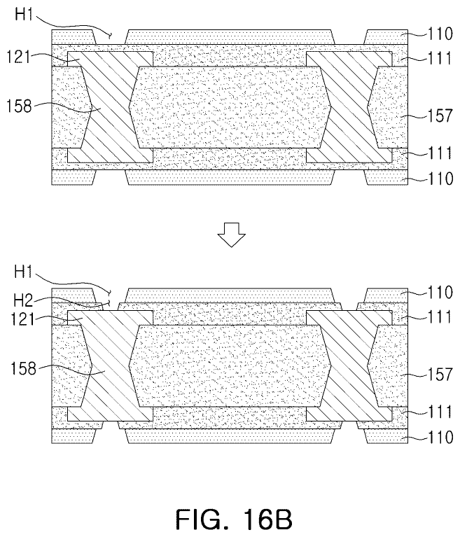

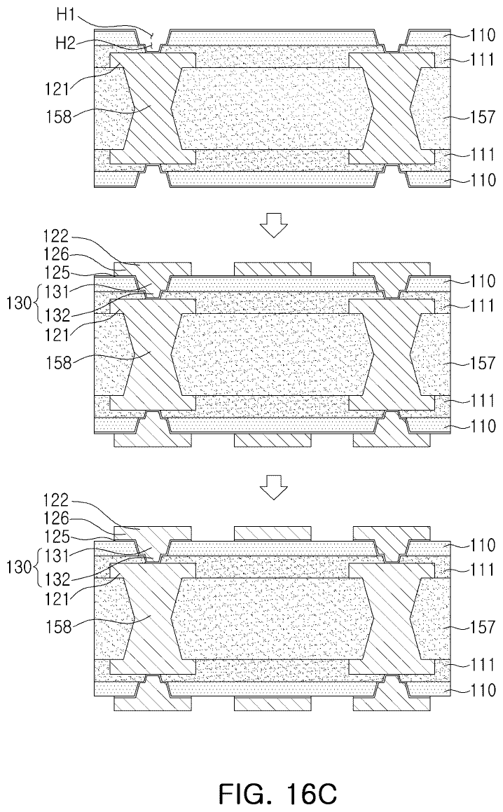

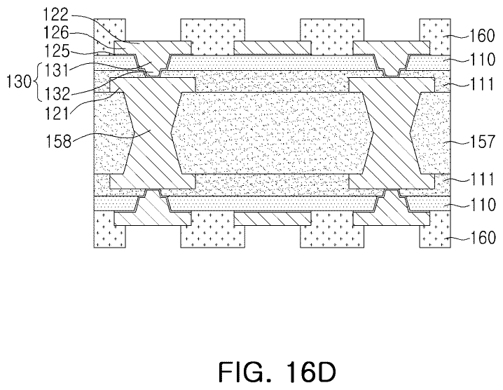

FIGS. 16A to 16D are schematic cross-sectional views illustrating a method of manufacturing the printed circuit board according to the sixth application example of the first exemplary embodiment illustrated in FIG. 15A.

The method of manufacturing a printed circuit board according to the sixth application example of the first exemplary embodiment may further include forming a first wiring layer 121 on the core layer 157, and forming a first insulating layer 111 on the core layer 157 to cover at least a portion of the first wiring layer 121. That is, it may be understood, in the method of manufacturing a printed circuit board according to the first exemplary embodiment described with reference to FIGS. 4A to 4C, that the insulating material 100 corresponds to the core layer 157.

The other configurations in FIGS. 16A to 16D may be substantially the same as those in the method of forming the interlayer structure of the printed circuit board according to the first exemplary embodiment, and thus, detailed description thereof will be omitted. Meanwhile, the forming of the through-holes penetrating the glass layer 110 and the first insulating layer 111 is briefly expressed, and detailed information about this may be replaced with the description about the printed circuit board and the method of manufacturing the printed circuit board according to the first exemplary embodiment as described above.

In addition, the printed circuit boards and the methods of manufacturing the same according to the first to seventh application examples are not limited to the configurations illustrated in the drawings, and other configurations may further be included, or any of the configurations illustrated in the drawings may be omitted in a certain case. That is, the printed circuit board may further include configurations that can be used by those skilled in the art, not limited to the configurations illustrated in the drawings.

As set forth above, according to the exemplary embodiments in the present disclosure, it is possible to provide a printed circuit board including a glass layer and a method of manufacturing the same.

In addition, it is possible to provide a printed circuit board capable of preventing warpage with improved flatness and a method of manufacturing the same.

In addition, it is possible to provide a printed circuit board capable of improving reliability and a method of manufacturing the same.

While exemplary embodiments have been shown and described above, it will be apparent to those skilled in the art that modifications and variations could be made without departing from the scope of the present invention as defined by the appended claims.

What is claimed is:

1. A printed circuit board comprising:
a first insulating layer;
a first wiring layer embedded in the first insulating layer on one side thereof;
a glass layer disposed on other side, opposite to the one side of the first insulating layer;
a second wiring layer disposed on the glass layer; and
a first via layer connecting the first wiring layer and the second wiring layer to each other, and including a first via portion penetrating the glass layer and a second via portion penetrating the first insulating layer,
wherein in a cross-sectional view of the printed circuit board, at least one of the first via portion and the second via portion has a width becoming substantially narrower toward the first wiring layer.

2. The printed circuit board of claim 1, wherein the first via portion and the second via portion are integral.

3. The printed circuit board of claim 1, wherein the second via portion has a smaller width than the first via portion at an interface between the first insulating layer and the glass layer.

4. The printed circuit board of claim 1, wherein the second wiring layer has a greater width than the first via portion at an interface between the glass layer and the second wiring layer.

5. The printed circuit board of claim 1, wherein the first via portion and the second via portion have substantially the same width at an interface between the glass layer and the first insulating layer.

6. The printed circuit board of claim 5, wherein an inclination angle between a side surface of the first via portion and other surface opposite to one surface of the first insulating layer is larger than an inclination angle between a side surface of the second via portion and one surface of the first wiring layer.

7. The printed circuit board of claim 1, wherein the first via layer includes a groove portion disposed on one side of the first via portion and embedded in at least a portion of the first insulating layer.

8. The printed circuit board of claim 7, wherein the groove portion is spaced apart from the second via portion, and is disposed along a perimeter of the second via portion.

9. The printed circuit board of claim 1, wherein the first via layer includes a recess portion disposed on one side of the first via portion and having a step from other surface opposite to one surface of the first insulating layer.

10. The printed circuit board of claim 1, wherein in the cross-sectional view of the printed circuit board, the first via portion is substantially perpendicular to the first insulating layer.

11. The printed circuit board of claim 1, wherein in the cross-sectional view of the printed circuit board, the second via portion is substantially perpendicular to the first wiring layer.

12. The printed circuit board of claim 1, wherein the second via portion has a larger width than the first via portion at an interface between the first insulating layer and the glass layer.

13. The printed circuit board of claim 1, wherein at least one first via of the first via layer includes one second via portion and a plurality of first via portions each contacting the one second via portion.

14. The printed circuit board of claim 13, wherein the first via includes a groove portion disposed on one side of at least one of the plurality of first via portions and embedded in at least a portion of the first insulating layer.

15. The printed circuit board of claim 13, wherein in the cross-sectional view of the printed circuit board, each of the plurality of first via portions has a width becoming narrower toward the first wiring layer.

16. The printed circuit board of claim 1, further comprising an adhesive layer interposed between the glass layer and the first insulating layer.

17. The printed circuit board of claim 16, wherein the first via portion penetrates at least a portion of the adhesive layer.

18. The printed circuit board of claim 16, wherein the second via portion penetrates at least a portion of the adhesive layer.

19. The printed circuit board of claim 16, wherein the adhesive layer includes an inorganic oxide film or an organic film.

20. The printed circuit board of claim 1, further comprising a second insulating layer disposed on the glass layer,
wherein the second wiring layer is disposed on the second insulating layer, and
the first via layer includes a third via portion penetrating the second insulating layer.

21. The printed circuit board of claim 20, wherein in the cross-sectional view of the printed circuit board, each of the first via portion, the second via portion, and the third via portion has a width becoming narrower toward the first wiring layer.

22. The printed circuit board of claim 20, wherein the first via portion has a smaller width than the third via portion at an interface between the glass layer and the second insulating layer, and
the second via portion has a smaller width than the first via portion at an interface between the glass layer and the first insulating layer.

23. The printed circuit board of claim 20, wherein the first via portion has a larger width than the third via portion at an interface between the glass layer and the second insulating layer.

24. The printed circuit board of claim 20, wherein the first via portion has a step between one surface and other surface opposite to one surface of the glass layer.

25. The printed circuit board of claim 1, wherein a surface roughness of the glass layer at an interface between the first insulating layer and the glass layer is smaller than a surface roughness of the glass layer at an interface between the first via layer and the glass layer.

26. The printed circuit board of claim 25, wherein the surface roughness of the glass layer at the interface between the first insulating layer and the glass layer is smaller than a surface roughness of the glass layer at an interface between the second wiring layer and the glass layer.

27. The printed circuit board of claim 1, wherein the first via portion has a larger depth than the second via portion.

28. The printed circuit board of claim 1, further comprising:
a build-up insulating layer disposed on the glass layer, and covering at least a portion of the second wiring layer;
a build-up wiring layer disposed on the build-up insulating layer; and
a build-up via layer penetrating at least a portion of the build-up insulating layer to connect the build-up wiring layer and the second wiring layer to each other.

29. The printed circuit board of claim 1, further comprising:
a build-up insulating layer disposed on one side of the first insulating layer;
a build-up wiring layer embedded in the build-up insulating layer on one side of the build-up insulating layer; and
a build-up via layer penetrating at least a portion of the build-up insulating layer to connect the build-up wiring layer and the first wiring layer to each other.

30. The printed circuit board of claim 1, further comprising a solder resist layer disposed on one side of the first insulating layer and covering at least a portion of the first wiring layer.

31. The printed circuit board of claim 30, further comprising a surface treatment layer disposed on at least a portion of the first wiring layer exposed by the solder resist layer.

32. The printed circuit board of claim 1, further comprising a solder resist layer disposed on the glass layer and covering at least a portion of the second wiring layer.

33. The printed circuit board of claim 1, further comprising:
a core layer of which one side is disposed on one side of the first insulating layer; and
a through via penetrating at least a portion of the core layer.

34. The printed circuit board of claim 33, wherein the first insulating layer, the first wiring layer, the glass layer, the second wiring layer, and the first via layer are further disposed on other side, opposite to the one side of the core layer, and
the through via connects the first wiring layers respectively disposed on the opposite sides of the core layer to each other.

35. The printed circuit board of claim 33, further comprising:
a build-up insulating layer disposed on other side of the core layer opposing the one side of the core layer;
build-up wiring layers disposed on the other side, opposite to the one side of the core layer and the build-up insulating layer, respectively; and
a build-up via layer penetrating at least a portion of the build-up insulating layer to connect the build-up wiring layers to each other.

36. A printed circuit board comprising:
an insulating layer;
a first wiring layer disposed on one side of the insulating layer;
a glass layer disposed on other side, opposite to the one side of the insulating layer;
a via layer including a first through-hole penetrating the insulating layer and exposing at least a portion of the first wiring layer, a second through-hole penetrating the glass layer and connected to the first through-hole, a portion of a first metal layer disposed on at least a partially exposed portion of the first wiring layer and a wall of each of the first and second through-holes, and a portion of a second metal layer disposed on the first metal layer and disposed in at least a portion of each of the first and second through-holes; and
a second wiring layer disposed on the glass layer and connected to the via layer.

37. The printed circuit board of claim 36, wherein the first metal layer extends continuously on at least the partially exposed portion of the first wiring layer and the wall of each of the first and second through-holes.

38. The printed circuit board of claim 36, wherein another portion of each of the first and second metal layers extends onto the glass layer, and
the second wiring layer includes the another portion of each of the first and second metal layers extending onto the glass layer.

39. A method of manufacturing a printed circuit board, the method comprising:
forming a first insulating layer embedding a first wiring layer;
forming a glass layer on the first insulating layer;
forming a first through-hole penetrating the glass layer;
forming a second through-hole penetrating the first insulating layer and exposing at least a portion of the first wiring layer;
forming a first via layer in the first through-hole and the second through-hole; and
forming a second wiring layer connected to the first via layer on the first insulating layer.

40. The method of claim 39, wherein in the forming of the first via layer, the first through-hole and the second through-hole are filled simultaneously.

41. The method of claim 39, wherein the forming of the first via layer includes forming a seed layer along inner walls of the first and second through-holes and forming a plating layer on the seed layer.

42. The method of claim 39, wherein the forming of the first through-hole includes forming a first hole penetrating the glass layer and removing a portion of the first insulating layer, and forming the first through-hole by removing a portion of the glass layer adjoining the first hole.

43. The method of claim 42, wherein the first hole is formed by emitting a laser to process the glass layer and the first insulating layer, and
the first through-hole is formed by etching.

44. The method of claim 42, wherein in the forming of the first through-hole, at least a portion of the first hole expands, and at least a portion of an upper portion of the glass layer is removed.

45. The method of claim 39, further comprising forming an adhesive layer on the first insulating layer before the forming of the glass layer,
wherein the glass layer is formed on the adhesive layer.

46. The method of claim 45, further comprising forming an opening by removing at least a portion of the adhesive layer after the forming of the first through-hole.

47. The method of claim 45, further comprising: before the forming of the first through-hole,
forming a second insulating layer on the glass layer; and
forming a third through-hole penetrating at least a portion of the second insulating layer.

48. The method of claim 39, further comprising:
forming the first wiring layer on a carrier substrate before the forming of the first insulating layer; and
removing the carrier substrate after the forming of the second wiring layer.

49. The method of claim 39, further comprising forming the first wiring layer on build-up layers before the forming of the first insulating layer,
wherein the build-up layers include build-up insulating layers, build-up wiring layers disposed on or in the build-up insulating layers, build-up via layers penetrating at least portions of the build-up insulating layers to connect the build-up wiring layers to each other.

50. The method of claim 39, further comprising forming the first wiring layer on a core layer before the forming of the first insulating layer.

51. The method of claim 39, further comprising forming build-up layers on the glass layer after the forming of the second wiring layer,
wherein the build-up layers include build-up insulating layers, build-up wiring layers disposed on the build-up insulating layers, build-up via layers penetrating at least portions of the build-up insulating layers to connect the build-up wiring layers to each other.

52. A printed circuit board comprising:
a first insulating layer;
a glass layer disposed on the first insulating layer;
a plurality of wiring layers including first and second wring layers respectively attached to the first insulating layer and the glass layer; and
a via layer connecting the first wiring layer and the second wiring layer to each other, and including a first via portion disposed in the glass layer and a second via portion extending from the first via portion and disposed in the first insulating layer,
wherein a surface roughness of one surface of the glass layer facing the first insulating layer is smaller than a surface roughness of another surface of the glass layer opposing the one surface of the glass layer.

53. The printed circuit board of claim 52, wherein the second via portion has a smaller width than the first via portion at an interface between the first insulating layer and the glass layer.

54. The printed circuit board of claim 52, wherein the first via portion and the second via portion have substantially the same width at an interface between the glass layer and the first insulating layer.

55. The printed circuit board of claim 52, wherein the via layer includes a groove portion disposed on one side of the first via portion and embedded in at least a portion of the first insulating layer.

56. The printed circuit board of claim 55, wherein the groove portion is spaced apart from the second via portion, and is disposed along a perimeter of the second via portion.

57. The printed circuit board of claim 52, wherein the second via portion has a larger width than the first via portion at an interface between the first insulating layer and the glass layer.

58. The printed circuit board of claim 52, wherein at least one first via of the via layer includes one second via portion and a plurality of first via portions each contacting the one second via portion.

59. The printed circuit board of claim 52, further comprising an adhesive layer interposed between the glass layer and the first insulating layer,
wherein the via layer penetrates at least a portion of the adhesive layer.

60. The printed circuit board of claim 52, wherein the plurality of wiring layers are spaced apart from a region between the first insulating layer and the glass layer.

61. The printed circuit board of claim 52, further comprising a second insulating layer disposed on the glass layer,
wherein the second wiring layer is disposed on the second insulating layer, and
the via layer includes a third via portion penetrating the second insulating layer.

62. The printed circuit board of claim 61, wherein the plurality of wiring layers are spaced apart from a region between the second insulating layer and the glass layer.

63. The printed circuit board of claim 52, wherein the surface roughness of the one surface of the glass layer is smaller than a surface roughness of a wall of a via hole in the glass layer in which the first via portion is disposed.
